(19) United States
(12) Patent Application Publication
(10) Pub. No.: US 2026/0080830 A1
(43) Pub. Date: Mar. 19, 2026

(54) DISPLAY PANEL AND DISPLAY DEVICE

(71) Applicant: Tianma Advanced Display Technology Institute (Xiamen) Co., Ltd., Xiamen (CN)

(72) Inventors: Zhenyu Jia, Xiamen (CN); Yingteng Zhai, Xiamen (CN); Kerui Xi, Xiamen (CN); Tianyi Wu, Xiamen (CN); Bo Yang, Xiamen (CN); Fanqing Meng, Xiamen (CN); Mingyan Xu, Xiamen (CN); Jiajie Li, Xiamen (CN)

(73) Assignee: Tianma Advanced Display Technology Institute (Xiamen) Co., Ltd., Xiamen (CN)

(21) Appl. No.: 19/397,351

(22) Filed: Nov. 21, 2025

(30) Foreign Application Priority Data
Dec. 18, 2024 (CN) 202411874093.0

(51) Int. Cl. G09G 3/3233; G09G 3/32; H10K 59/121; H10K 59/131

(52) U.S. Cl. CPC G09G 3/3233; H10K 59/1213; H10K 59/1216; H10K 59/1315; G09G 3/32; G09G 2300/0426; G09G 2300/0852; G09G 2300/0861; G09G 2320/0252

(57) ABSTRACT

Provided are a display panel and a display device. The display panel includes a substrate, a pixel circuit and a light-emitting unit. The pixel circuit and the light-emitting unit are located on one side of the substrate. The pixel circuit includes a first node electrically connected to a first power line and a second node electrically connected to the light-emitting unit. The pixel circuit includes a first transistor coupled between the first node and the second node and including a first electrode including a first portion extending in a first direction and a second electrode including a second portion extending in a second direction intersecting with the first direction. The driving delay of the first transistor can be improved, and the layout structure of the pixel circuit can be simplified.

The present application claims priority to Chinese Patent Application No. 202411874093.0, filed on Dec. 18, 2024, the content of which is incorporated herein by reference in its entirety.

### TECHNICAL FIELD

The present disclosure relates to the field of display technologies and, in particular, to a display panel and a display device.

### BACKGROUND

In existing display panels, transistors with a large width-to-length ratio are generally provided in pixel circuits to meet requirements of driving a light-emitting device with a large current. However, the arrangement of these transistors may increase the design difficulty of the layout of the pixel circuit, which may cause overlapping between some electrodes of the transistors, thereby resulting in an excessive load of driving signal lines connected to the transistors. This may further lead to a delay of the driving signals and affect the display effect of the display panel. Therefore, there is an urgent need for a solution.

### SUMMARY

In view of this, embodiments of the present disclosure provide a display panel and a display device to solve the above-mentioned problems.

In a first aspect, an embodiment of the present disclosure provides a display panel, including a substrate, a pixel circuit, and a light-emitting unit. The pixel circuit and the light-emitting unit are located at one side of the substrate, the pixel circuit includes a first node electrically connected to a first power line and a second node electrically connected to the light-emitting unit, the pixel circuit includes a first transistor coupled between the first node and the second node, and the first transistor includes a first electrode and a second electrode. The first electrode includes a first portion extending in a first direction, the second electrode includes a second portion extending in a second direction, and the first direction intersects with the second direction. The first portion includes a first sub-portion and a second sub-portion connected to each other, and an orthographic projection of the second sub-portion on the substrate overlaps with an orthographic projection of the second portion on the substrate. In the second direction, a width of the first sub-portion is greater than a width of the second sub-portion.

In a second aspect, an embodiment of the present disclosure provides a display device. The display device includes a display panel including a substrate, a pixel circuit, and a light-emitting unit. The pixel circuit and the light-emitting unit are located at one side of the substrate, the pixel circuit includes a first node electrically connected to a first power line and a second node electrically connected to the light-emitting unit, the pixel circuit includes a first transistor coupled between the first node and the second node, and the first transistor includes a first electrode and a second electrode. The first electrode includes a first portion extending in a first direction, the second electrode includes a second portion extending in a second direction, and the first direction intersects with the second direction. The first portion includes a first sub-portion and a second sub-portion connected to each other, and an orthographic projection of the second sub-portion on the substrate overlaps with an orthographic projection of the second portion on the substrate. In the second direction, a width of the first sub-portion is greater than a width of the second sub-portion

### BRIEF DESCRIPTION OF DRAWINGS

In order to more clearly illustrate the technical solutions in the embodiments of the present disclosure, the drawings, which are intended to be used in the description of the embodiments, are briefly described as below. It should be understood that other drawings described below are merely some embodiments of the present disclosure, and that other drawings may be obtained by those skilled in the art according to these drawings without paying any creative efforts.

FIG. 1 is a schematic diagram of a display panel according to an embodiment of the present disclosure.

FIG. 2 is a schematic diagram of a pixel circuit according to an embodiment of the present disclosure.

FIG. 3 is a schematic layout diagram of a first transistor shown in FIG. 2.

FIG. 4 is another schematic layout diagram of the first transistor shown in FIG. 2.

FIG. 5 is a schematic diagram of another pixel circuit according to an embodiment of the present disclosure.

FIG. 6 is a partial schematic layout diagram of the pixel circuit shown in FIG. 5.

FIG. 7 is a schematic layout diagram of a first transistor according to an embodiment of the present disclosure.

FIG. 8 is a partial schematic layout diagram of a pixel circuit according to an embodiment of the present disclosure.

FIG. 9 is a partial schematic layout diagram of another pixel circuit according to an embodiment of the present disclosure.

FIG. 10 is a partial schematic layout diagram of another pixel circuit according to an embodiment of the present disclosure.

FIG. 11 is a partial schematic layout diagram of another pixel circuit according to an embodiment of the present disclosure.

FIG. 12 is a partial schematic layout diagram of another pixel circuit according to an embodiment of the present disclosure.

FIG. 13 is a partial schematic layout diagram of another pixel circuit according to an embodiment of the present disclosure.

FIG. 14A is a partial schematic layout diagram of another pixel circuit according to an embodiment of the present disclosure.

FIG. 14B is a schematic cross-sectional view of a first transistor shown in FIG. 14A.

FIG. 15 is a schematic diagram of another pixel circuit according to an embodiment of the present disclosure.

FIG. 16 is a schematic diagram of a pixel circuit according to an embodiment of the present disclosure.

FIG. 17 is a schematic layout diagram of a pixel circuit according to an embodiment of the present disclosure.

FIG. 18 is a schematic cross-sectional view of a first capacitor shown in FIG. 17.

FIG. 19 is an enlarged schematic diagram of a first capacitor according to an embodiment of the present disclosure.

FIG. 20A is a schematic diagram of a film layer of a first metal layer in the pixel circuit shown in FIG. 17.

FIG. 20B is a schematic diagram of a film layer of an active layer in the pixel circuit shown in FIG. 17.

FIG. 20C is a schematic diagram of a film layer of a second metal layer in the pixel circuit shown in FIG. 17.

FIG. 20D is a schematic diagram of a film layer of a third metal layer in the pixel circuit shown in FIG. 17.

FIG. 20E is a schematic diagram of a film layer of a fourth metal layer in the pixel circuit shown in FIG. 17.

FIG. 21 is a schematic comparison diagram of a first transistor according to an embodiment of the present disclosure.

FIG. 22 is a schematic diagram of a display device according to an embodiment of the present disclosure.

FIG. 23 is a schematic diagram of another display device according to an embodiment of the present disclosure.

### DESCRIPTION OF EMBODIMENTS

To better understand the technical solutions of the present disclosure, embodiments of the present disclosure are described in detail below in conjunction with the drawings.

It should be understood that the described embodiments are just some, rather than all, of the embodiments of the present disclosure. All other embodiments obtained by a person having ordinary skill in the art that are based on the embodiments in the present disclosure without creative efforts should be understood to fall within the protection scope of the present disclosure.

The terms used in the embodiments of the present disclosure are only for the purpose of describing specific embodiments, and are not intended to limit the present disclosure. The singular forms “a/an”, “said”, and “the” used in the embodiments of the present disclosure and the attached claims are also intended to include plural forms thereof, unless noted otherwise.

It should be understood that the term “and/or” used herein is merely an association relationship describing an associated object, and indicates that there may be three relationships. For example, A and/or B, and may indicate: A alone, both A and B, and B alone. In addition, the character “/” herein generally denotes an “or” relationship between the associated objects prior to and subsequent to the character.

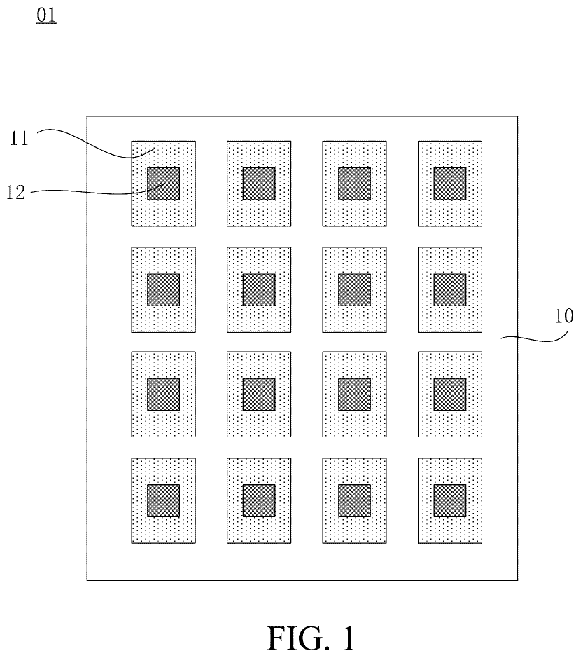

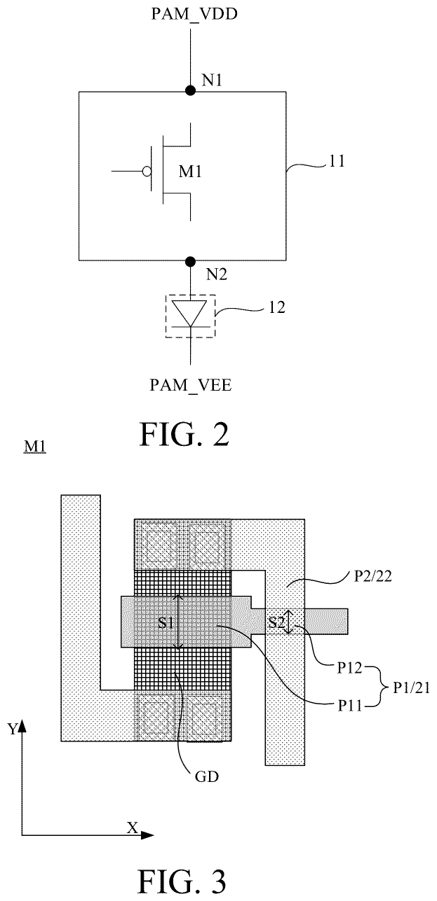

FIG. 1 is a schematic diagram of a display panel according to an embodiment of the present disclosure. FIG. 2 is a schematic diagram of a pixel circuit according to an embodiment of the present disclosure. FIG. 3 is a schematic layout diagram of a first transistor shown in FIG. 2.

An embodiment of the present disclosure provides a display panel 01. According to the embodiment shown in FIG. 1, the display panel 01 includes a substrate 10, a pixel circuit 11, and a light-emitting unit 12. The pixel circuit 11 and the light-emitting unit 12 are located at one side of the substrate 10, and the pixel circuit 11 is configured to drive the light-emitting unit 12 to emit light.

In some embodiments, the light-emitting unit 12 is any one of a micro light-emitting diode (Micro-LED), a mini light-emitting diode (Mini-LED), and an organic light-emitting diode (OLED).

According to the embodiment shown in FIG. 2, the pixel circuit 11 has a first node N1 and a second node N2. The first node N1 may be electrically connected to a first power line PAM_VDD, and the second node N2 may be electrically connected to the light-emitting unit 12.

In some embodiments, the second node N2 is electrically connected to a first electrode of the light-emitting unit 12, and a second electrode of the light-emitting unit 12 is electrically connected to a second power line PAM_VEE. In some embodiments, the first power line PAM_VDD transmits a power voltage PVDD, the second power line PAM_VEE transmits a power voltage PVEE, and the first electrode of the light-emitting unit 12 serves as an anode.

In some embodiments, the pixel circuit 11 includes a first transistor M1 coupled between the first node N1 and the second node N2. According to the embodiment shown in FIG. 3, the first transistor M1 includes a first electrode 21 and a second electrode 22. The first electrode 21 includes a first portion P1 extending along a first direction X, and the second electrode 22 includes a second portion P2 extending along a second direction Y. The first direction X intersects with the second direction Y.

In some embodiments, the first direction X is a row direction of the display panel 01, and the second direction Y is a column direction of the display panel 01.

The first portion P1 may include a first sub-portion P11 and a second sub-portion P12 connected to each other, and an orthographic projection of the second sub-portion P12 on the substrate 10 overlaps with an orthographic projection of the second portion P2 on the substrate 10.

In the second direction Y, a width of the first sub-portion P11 may be greater than a width of the second sub-portion P12.

In some embodiments, such as the embodiment shown in FIG. 3, in the second direction Y, the second sub-portion P12 is formed as a continuous structure. The width of the first sub-portion P11 is S1, and the width of the second sub-portion P12 is S2, such that S1>S2. Herein, the second sub-portion P12 being formed as a continuous structure means that the second sub-portion P12 does not include a hollow region in the second direction Y.

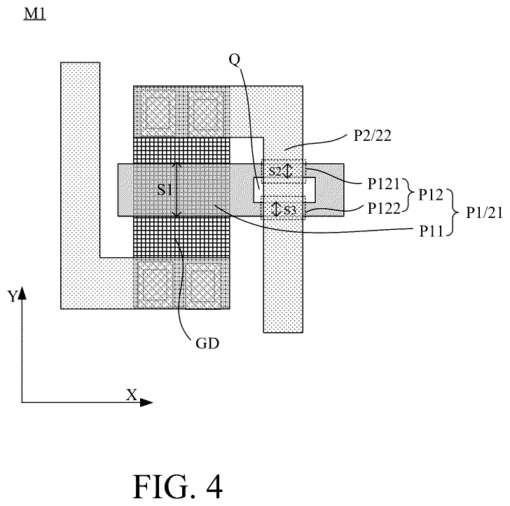

In some embodiments, such as the embodiment shown in FIG. 4 is another schematic layout diagram of the first transistor shown in FIG. 2. In some embodiments, the second sub-portion P12 is formed as a discontinuous structure in the second direction Y. The second sub-portion P12 includes a first section P121 and a second section P122 arranged in the second direction Y. A hollow region Q may be provided between the first section P121 and the second section P122, and an orthographic projection of the hollow region Q on the substrate 10 may overlap with an orthographic projection of the second portion P2 on the substrate 10. In the second direction Y, the width of the first sub-portion P11 is S1, the width of the first section P121 is S2, and a width of the second section P122 is S3, where S1>S2+S3.

In some embodiments, a length of the hollow region Q may be greater than or equal to a length of the second portion P2 in the first direction X.

When the first electrode and the second electrode of the first transistor M1 overlap in the direction perpendicular to the plane of the display panel 01, a parasitic capacitance may be generated between the first electrode and the second electrode, which may be prone to increasing the load of the driving signal for driving the first transistor M1, resulting in the delay of the driving signal and thus the delay in turning on or turning off the first transistor M1, and affecting the display effect.

In view of this, in some embodiments of the present disclosure, when the second sub-portion P12 is configured with a smaller width in the second direction Y, the area of the second sub-portion P12 extending in the first direction X is reduced. This may reduce an overlapping area between the second sub-portion P12 and the second portion P2 in the direction perpendicular to the plane of the display panel 01, thereby reducing the parasitic capacitance between the second sub-portion P12 and the second portion P2 and further reducing the parasitic capacitance between the first electrode 21 and the second electrode 22.

When driving the first transistor M1, the first electrode 21 or the second electrode 22 of the first transistor M1 may receive a driving signal. Because the parasitic capacitance between the first electrode 21 and the second electrode 22 is reduced, the load of the driving signal may be reduced, thereby improving the response delay problem of the first transistor M1 and enhancing the display effect of the display panel 01.

In some embodiments, such as the embodiments shown in FIG. 3 and FIG. 4, the first electrode 21 is a gate, and the second electrode 22 is a source or a drain.

In some embodiments, regarding the first electrode P1, because the width of the first sub-portion P11 in the second direction Y is relatively large, the cross-sectional area of the first sub-portion P11 may be increased. This may reduce the resistance of the first sub-portion P11, thereby reducing the resistance of the first portion P1, and further reducing the resistance of the first electrode 21. Because the present disclosure may also reduce the parasitic capacitance between the first electrode 21 and the second electrode 22, in the present disclosure the resistance-capacitance (RC) load on the first electrode 21 may also be reduced.

When the first electrode 21 is configured as a gate, the first electrode 21 may receive a driving signal when driving the first transistor M1, which may reduce the RC load of the driving signal to a greater extent, and further improve the response delay problem of the first transistor M1.

In some embodiments, such as the embodiments shown in FIG. 3 and FIG. 4, the first transistor M1 further includes a channel GD. In the first electrode 21, an orthographic projection of the first sub-portion P11 on the substrate 10 overlaps with an orthographic projection of the channel GD on the substrate 10, and an orthographic projection of the second sub-portion P12 on the substrate 10 does not overlap with the orthographic projection of the channel GD on the substrate 10.

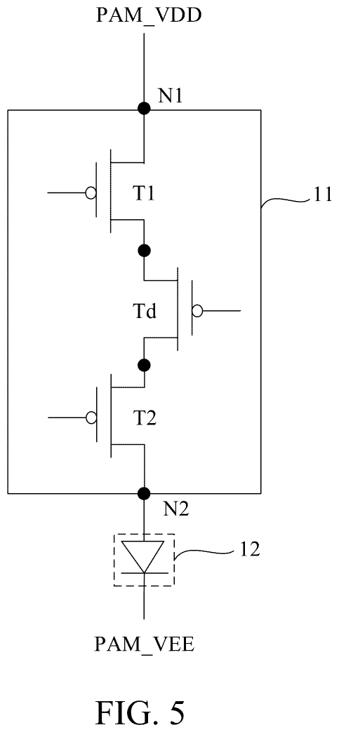

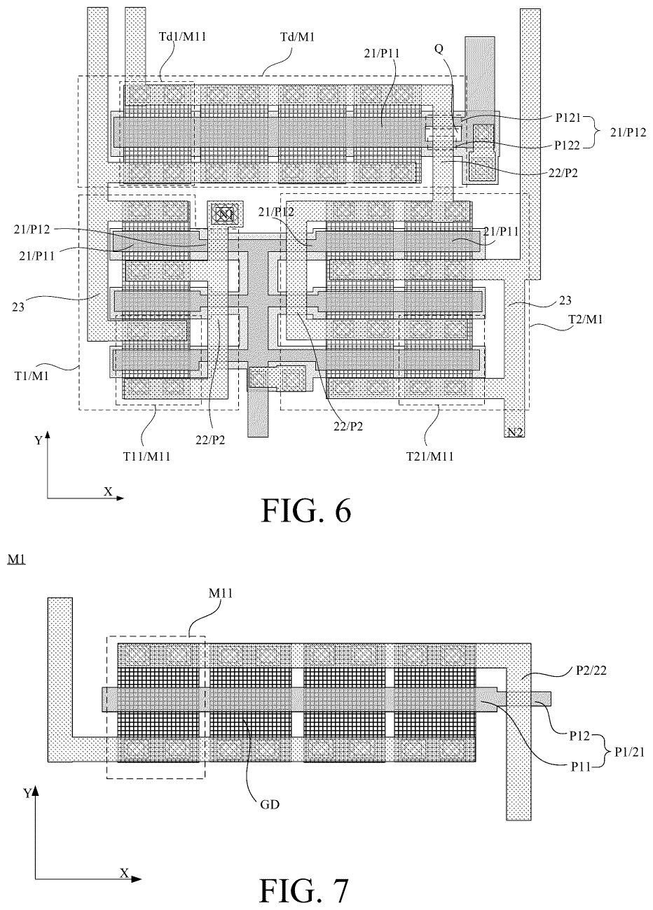

FIG. 5 is a schematic diagram of another pixel circuit according to an embodiment of the present disclosure. FIG. 6 is a partial schematic layout diagram of the pixel circuit shown in FIG. 5.

In an embodiment of the present disclosure, as depicted in FIG. 5 and FIG. 6, the pixel circuit 11 includes a first light-emitting control transistor T1, a first driving transistor Td, and a second light-emitting control transistor T2. The first light-emitting control transistor T1 may be coupled between the first node N1 and the first driving transistor Td, and the second light-emitting control transistor T2 may be coupled between the first driving transistor Td and the second node N2. In this way, a light-emitting driving current generated by the pixel circuit 11 may be transmitted to the light-emitting unit 12 sequentially through the first light-emitting control transistor T1, the first driving transistor Td, and the second light-emitting control transistor T2.

In some embodiments, such as the embodiments shown in FIG. 5 and FIG. 6, a source of the first light-emitting control transistor T1 is electrically connected to the first node N1 for receiving the first power voltage PVDD. A drain of the first light-emitting control transistor T1 may be electrically connected to a source of the first driving transistor Td. A drain of the first driving transistor Td may be electrically connected to a source of the second light-emitting control transistor T2. A drain of the second light-emitting control transistor T2 may be electrically connected to the second node N2. The first node N1 may be a position where an via hole in the pixel circuit 11 is communicated to a first power line DL1, and the second node N2 is a position where a via hole in the pixel circuit 11 is communicated to the light-emitting unit 12.

In some embodiments, at least one of the first light-emitting control transistor T1, the first driving transistor Td, and the second light-emitting control transistor T2 is the first transistor M1. That is, the first electrode 21 and the second electrode 22 of at least one of the first light-emitting control transistor T1, the first driving transistor Td, and the second light-emitting control transistor T2 overlap with each other in the direction perpendicular to the plane of the display panel 01. As such, the parasitic capacitance between the first electrode 21 and the second electrode 22 is reduced by configuring the second sub-portion P12 with a smaller width.

Such an arrangement, as can be understood from the foregoing analysis, may reduce the driving signal load of at least one of the first light-emitting control transistor T1, the first driving transistor Td, and the second light-emitting control transistor T2, thereby improving the response delay problem of at least one of the first light-emitting control transistor T1, the first driving transistor Td, and the second light-emitting control transistor T2.

Because the light-emitting driving current transmitted to the light-emitting unit 12 flows through the first light-emitting control transistor T1, the first driving transistor Td, and the second light-emitting control transistor T2, the response delay of at least one of the first light-emitting control transistor T1, the first driving transistor Td and the second light-emitting control transistor T2 has been improved. This may enhance the timeliness of transmitting the light-emitting driving current to the light-emitting unit 12, thereby increasing the response speed of the light-emitting unit 12 and enhancing the display effect of the display panel.

For example, according to the embodiments shown in FIG. 5 and FIG. 6, the first light-emitting control transistor T1, the first driving transistor Td and the second light-emitting control transistor T2 are all the first transistor M1, increasing the response speed of the light-emitting unit 12 to a greater extent.

In some embodiments, such as the embodiment shown in FIG. 6, the first light-emitting control transistor T1 and the second light-emitting control transistor T2 are located on the same side of the first driving transistor Td. The first light-emitting control transistor T1 and the second light-emitting control transistor T2 are arranged along the first direction X, and the first light-emitting control transistor T1 and the first driving transistor Td are arranged along the second direction Y.

Based on this arrangement, connection lines between the first driving transistor Td and the first light-emitting control transistor T1 and the connection lines between the first driving transistor Td and the second light-emitting control transistor T2 may be arranged along the second direction Y, which allows the connection lines to remain substantially straight, thereby reducing the design difficulty of the layout of the pixel circuit 11, shortening the length of the connection lines, and reducing the impedance.

Further, the first electrode 21 of the first light-emitting control transistor T1 may be electrically connected to the first electrode 21 of the second light-emitting control transistor T2. That is, the gate of the first light-emitting control transistor T1 may be electrically connected to the gate of the second light-emitting control transistor T2. In this way, the first light-emitting control transistor T1 and the second light-emitting control transistor T2 may share the same switching state, which simplifies the control manner of the first light-emitting control transistor T1 and the second light-emitting control transistor T2.

Further, because the first light-emitting control transistor T1 and the second light-emitting control transistor T2 are arranged along the first direction X, the connection line between the gate of the first light-emitting control transistor T1 and the gate of the second light-emitting control transistor T2 can be integrally formed with the gate of the first light-emitting control transistor T1 and the gate of the second light-emitting control transistor T2, without the requirement for cross-lines. This may reduce the process difficulty of electrically connecting the gate of the first light-emitting control transistor T1 and the gate of the second light-emitting control transistor T2.

In some embodiments, such as the embodiment shown in FIG. 6, in the second direction Y, the second sub-portion P12 of the first light-emitting control transistor T1 and the second light-emitting control transistor T2 is formed as a continuous structure, and the second sub-portion P12 of the first light-emitting control transistor T1 and the second light-emitting control transistor T2 forms a “necking” structure relative to the first sub-portion P11 therein. In the second direction Y, the second sub-portion P12 of the first driving transistor Td is formed as a discontinuous structure, and the second sub-portion P12 of the first driving transistor Td includes a first section P121 and a second section P122. A hollow region Q is provided between the first section P121 and the second section P122.

FIG. 7 is a schematic layout diagram of a first transistor according to an embodiment of the present disclosure.

In some embodiments, such as the embodiment shown in FIG. 7, the first transistor M1 includes X sub-transistors M11, with first electrodes of the X sub-transistors M11 being connected to each other, second electrodes of the X sub-transistors M11 being connected to each other, and third electrodes of the X sub-transistors M11 being connected to each other. The first electrode may be the gate of the sub-transistor M11, the second electrode may be the source of the sub-transistor M11, and the third electrode may be the drain of the sub-transistor M11. It should be understood that, the gate, source and drain of the sub-transistor M11 may also respectively be referred to as the gate, source and drain of the first transistor M1. Further, X≥2 and is an integer. That is, the first transistor M1 includes at least two sub-transistors M11, with the gates of the sub-transistors M11 connected to each other, the sources of the sub-transistors M11 connected to each other, and the drains of the sub-transistors M11 connected to each other. Based on these connections, the first transistor M1 includes X sub-transistors M11 connected in parallel.

According to the embodiment shown in FIG. 7, in the first transistor M1, the sub-transistors M11 may be arranged along the first direction X. The sub-transistors M11 may also be arranged along the second direction Y. Further, the sub-transistors M11 may also be arranged in an array along the first direction X and the second direction Y. In the present disclosure, the arrangement of the sub-transistors M11 may be flexibly configured according to the layout space.

In some embodiments of the present disclosure, the first transistor M1 includes a plurality of sub-transistors M11, such that a channel width-to-length ratio (a sum of channel width-to-length ratios of sub-transistors) of the first transistor M1 is relatively large. The larger the channel width-to-length ratio of the transistor is, the larger the saturation current of the transistor is, thereby allowing the first transistor M1 to achieve greater driving capability. When the first transistor M1 is configured as a transistor for conducting the light-emitting driving current in the pixel circuit 11, the high-current driving capability of the pixel circuit 11 can be enhanced.

On this basis, because the first transistor M1 having a large channel width-to-length ratio has a relatively large inherent capacitance, reducing the parasitic capacitance between the first electrode 21 and the second electrode 22 of the first transistor M1 can significantly mitigate the driving signal delay of the first transistor M1, thereby enhancing the response speed of the first transistor M1.

As can be understood from the foregoing analysis, because at least one of the first light-emitting control transistor T1, the first driving transistor Td and the second light-emitting control transistor T2 may be the first transistor M1, at least one of the first light-emitting control transistor T1, the first driving transistor Td and the second light-emitting control transistor T2 may include a plurality of sub-transistors M11.

In some embodiments, such as the embodiment shown in FIG. 6, the first light-emitting control transistor T1 is a first transistor M1, and the first light-emitting control transistor T1 includes X1 first sub-transistors T11 connected in parallel, with gates of the X1 first sub-transistors T11 being connected to each other, sources of the X1 first sub-transistors T11 being connected to each other, and drains of the X1 first sub-transistors T11 being connected to each other. The X1 first sub-transistors T11 are arranged along the second direction Y, where X1≥2 and X1 is an integer. It should be understood that the first sub-transistor T11 is a sub-transistor in the first light-emitting control transistor T1.

In some embodiments, such as the embodiment shown in FIG. 6, the first light-emitting control transistor T1 includes three first sub-transistors T11 arranged along the second direction Y. The second light-emitting control transistor T2 is a first transistor M1, and the second light-emitting control transistor T2 includes X2 second sub-transistors T21 connected in parallel, with gates of the X2 second sub-transistors T21 connected to each other. Sources of the X2 second sub-transistors T21 connected to each other and drains of the X2 second sub-transistors T21 connected to each other. In some embodiments, the X2 second sub-transistors T21 are arranged in an array along the first direction X and the second direction Y, and X2≥2 and is an integer. It should be understood that the second sub-transistor T21 is a sub-transistor in the second light-emitting control transistor T2. In some embodiments, X1<X2.

In some embodiments, such as the embodiment shown in FIG. 6, the second light-emitting control transistor T2 includes six second sub-transistors T21 arranged in three rows and two columns. In the first direction X, two second sub-transistors T21 are sequentially arranged. In the second direction Y, three second sub-transistors T21 are sequentially arranged.

Because the first light-emitting control transistor T1 and the second light-emitting control transistor T2 are arranged along the first direction X, the first sub-transistor T11 in the first light-emitting control transistor T1 may be arranged along the second direction Y, and the second sub-transistor T21 in the second light-emitting control transistor T2 may be arranged along the first direction X and the second direction Y. There are benefits to reasonably distributing the occupied space of the first light-emitting control transistor T1 and the second light-emitting control transistor T2 in the first direction X and the second direction Y, so as to avoid the excessive space occupation of the first light-emitting control transistor T1 and the second light-emitting control transistor T2 in the first direction X. However, there are additional benefits to aligning the gate of the first sub-transistor T11 with the gate of the second sub-transistor T21, such that when the gate of the first light-emitting control transistor T1 is electrically connected with the gate of the second light-emitting control transistor T2, the connection line between the first light-emitting control transistor T1 and the second light-emitting control transistor T2 is relatively straight, thereby reducing the layout design complexity of the pixel circuit 11.

In some embodiments, the channel width-to-length ratio of the first sub-transistor T11 is equal to the channel width-to-length ratio of the second sub-transistor T21. Based on this arrangement, the structural complexity of the first light-emitting control transistor T1 and the second light-emitting control transistor T2 can be reduced, thereby reducing the manufacturing difficulty of the pixel circuit 11. However, such an arrangement improves alignment of the first sub-transistor T11 and the second sub-transistor T21 in the first direction X.

The first driving transistor Td may be a first transistor M1, and the first driving transistor Td may include X3 third sub-transistors Td1 connected in parallel, with gates of the X3 third sub-transistors Td1 connected to each other, sources of the X3 third sub-transistors Td1 connected to each other, and drains of the X3 third sub-transistors Td1 connected to each other. The X3 third sub-transistors Td1 may be arranged along the first direction X, where X3≥2 and X3 is an integer. It should be understood that the third sub-transistor Td1 is a sub-transistor in the first driving transistor Td.

Based on such an arrangement, the first driving transistor Td may have a larger channel width-to-length ratio. The larger the channel width-to-length ratio of the transistor is, the larger the saturation current of the transistor is, thereby allowing the first driving transistor Td to achieve greater driving capability, and further enhancing the large-current driving capability of the pixel circuit 11.

In some embodiments, the channel width-to-length ratio of the third sub-transistor Td1 is smaller than the channel width-to-length ratio of the first sub-transistor T11. Because the channel width-to-length ratio of the second sub-transistor T21 may be equal to the channel width-to-length ratio of the first sub-transistor T11, the channel width-to-length ratio of the third sub-transistor Td1 may also be smaller than the channel width-to-length ratio of the second sub-transistor T21. For example, referring to the embodiment depicted in FIG. 6, the first driving transistor Td includes four third sub-transistors Td1 arranged along the first direction X.

Because the first driving transistor Td and the first light-emitting control transistor T1 are arranged along the second direction Y, and the first light-emitting control transistor T1 and the second light-emitting control transistor T2 are arranged along the first direction X, the third sub-transistor Td1 in the first driving transistor Td may be arranged along the first direction X, so as to reasonably utilize the space of the pixel circuit 11 in the first direction X, enhance the compactness of the first driving transistor Td with the first light-emitting control transistor T1 and the second light-emitting control transistor T2, and prevent large blank areas from occurring in the layout of the pixel circuit 11.

In some embodiments, such as the embodiment shown in FIG. 6, a third electrode 23 (drain) connected to the second sub-transistor T21 is further away from the first sub-transistor T11 than a second electrode 22 (source) connected thereto. Because the drain of the second light-emitting control transistor T2 is electrically connected to the second node N2, based on such arrangement manner, the second node N2 may be arranged at a side of the second light-emitting control transistor T2 away from the first light-emitting control transistor T1, which facilitates reducing the number of traces between the first light-emitting control transistor T1 and the second light-emitting control transistor T2, and reducing the layout design complexity of the pixel circuit 01.

In some embodiments, such as the embodiment shown in FIG. 6, a third electrode 23 (drain) connected to the first sub-transistor T11 is further away from the second sub-transistor T21 than a second electrode 22 (source) connected thereto.

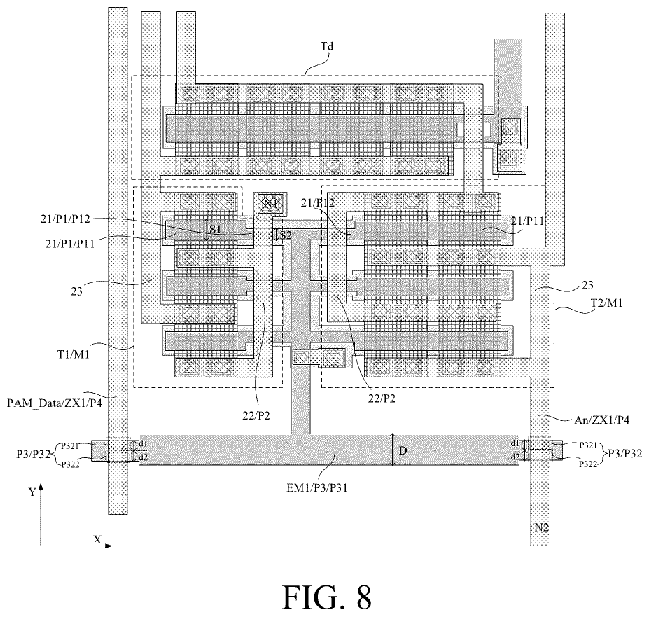

FIG. 8 is a partial schematic layout diagram of another pixel circuit according to an embodiment of the present disclosure.

In an embodiment of the present disclosure, as shown in FIG. 8, both the first light-emitting control transistor T1 and the second light-emitting control transistor T2 are the first transistor M1, and the first electrode 21 of the first transistor M1 is electrically connected to a first light-emitting control signal line EM1. That is, the gate of the first light-emitting control transistor T1 and the gate of the second light-emitting control transistor T2 are both electrically connected to the first light-emitting control signal line EM1.

In some embodiments, the first light-emitting control signal line EM1 is formed in the same layer as the gate of the first light-emitting control transistor T1 and the gate of the second light-emitting control transistor T2. The same process and material may be used for preparation.

The first light-emitting control signal line EM1 may include a third portion P3 extending along the first direction X, and the third portion P3 may be located at a side of the first light-emitting control transistor T1 away from the first driving transistor Td.

In the second direction Y, the width of the third portion P3 may be greater than the width of the first portion P1. It should be understood that, in the second direction Y, the width D of the third portion P3 may be greater than both the width S2 of the second sub-portion P12 in the first portion P1 and the width S1 of the first sub-portion P11 in the first portion P1.

It should be understood that the first light-emitting control signal line EM1 may be configured to transmit a driving signal to the first light-emitting control transistor T1 and the second light-emitting control transistor T2, and a load on the first light-emitting control signal line EM1 may also affect a response speed of the first light-emitting control transistor T1 and the second light-emitting control transistor T2.

Further, in the display panel 01, the pixel circuits 11 extending along the first direction X may be connected to the same first light-emitting control signal line EM1, and the length of the first light-emitting control signal line EM1 in the first direction X is relatively large.

Therefore, in some embodiments of the present disclosure, the third portion P3 has a larger width in the second direction Y, which facilitates enlarging the cross-sectional area of the first light-emitting control signal line EM1 and reducing a resistance of the first light-emitting control signal line EM1, thereby further reducing the load of the driving signal for driving the first transistor and enhancing the response speed of the first transistor. In particular, in the pixel circuit 11 connected to an end (an end away from a signal receiving end) of the first light-emitting control signal line EM1, the response speed of the first transistor therein can be significantly improved by reducing the resistance of the first light-emitting control signal line EM1.

In some embodiments, such as the embodiment shown in FIG. 8, in the second direction Y, a width of the third portion P3 is D, and 5.6 μm<D≤15 μm. In this way, reducing the resistance of the first light-emitting control signal line EM1 is advantageous in that it facilitates avoiding excessive increase of occupied space of the pixel circuit 11 in the second direction Y, and ensuring that a larger number of pixel circuits are arranged in the display panel 01 along the second direction Y, thereby ensuring that the display panel 01 has a relatively high pixel density.

In some embodiments, such as the embodiment shown in FIG. 8, the display panel 01 includes a first metal trace ZX1, which may be in the same layer as the second electrode 22 of the first transistor M1. The first metal trace ZX1 may include a fourth portion P4 extending along the second direction Y.

The third portion P3 of the first light-emitting control signal line EM1 may include a third sub-portion P31 and a fourth sub-portion P32 connected to each other, and an orthographic projection of the fourth sub-portion P32 on the substrate 10 may overlap with an orthographic projection of the fourth portion P4 on the substrate 10.

In some embodiments, the fourth sub-portion P32 includes a first connection portion P321 connected to the third sub-portion P31, and a width of the first connection portion P321 in the second direction Y is d1. The fourth sub-portion P32 includes a second connection portion P322 connected to the third sub-portion P31, and a width of the second connection portion P322 in the second direction Y is d2. A width of the third portion P3 in the second direction Y, then, is D, where d1+d2<D. That is, in the second direction Y, the width of the third portion P3 is greater than the sum of the widths of the first connection portion P321 and the second connection portion P322.

In some embodiments of the present disclosure, when the fourth sub-portion P32 is configured with a smaller width in the second direction Y, the area of the fourth sub-portion P32 is reduced, so as to reduce the overlapping area of the fourth sub-portion P32 and the fourth portion P4 in the direction perpendicular to the plane of the display panel 01. This may reduce the parasitic capacitance between the fourth sub-portion P32 and the fourth portion P4, further reducing the load on the first light-emitting control signal line EM1, and improving the response speed of the first transistor M1. In some embodiments, such as the embodiment shown in FIG. 8, in the second direction Y, the fourth sub-portion P32 is a continuous structure. The first connection portion P321 is connected to the second connection portion P322, and the fourth sub-portion P32 is designed to be “necking” relative to the third sub-portion P31. The sum of the widths of the first connection portion P321 and the second connection portion P322 in the second direction Y is the width of the fourth sub-portion P32 in the second direction Y.

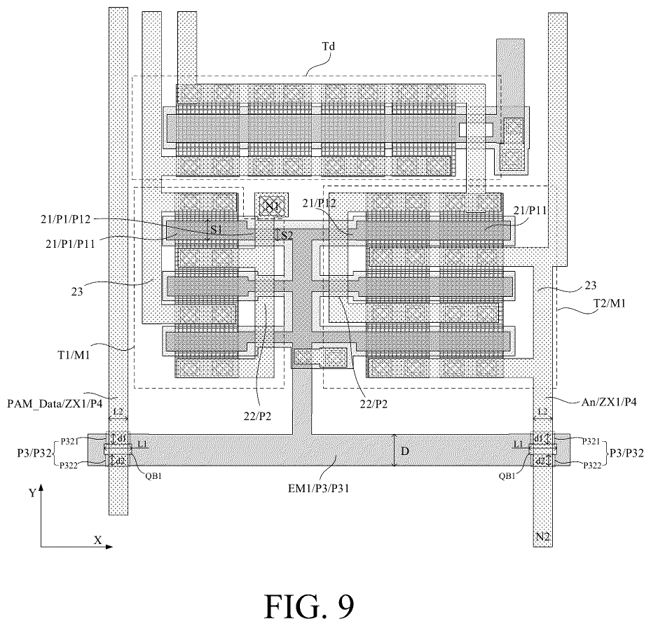

In some embodiments, such as the embodiment shown in FIG. 9, which is a partial schematic layout diagram of another pixel circuit according to an embodiment of the present disclosure, the fourth sub-portion P32 is a non-connection structure in the second direction Y. The first connection portion P321 and the second connection portion P322 may be arranged along the second direction Y, and a first hollow portion QB1 may be formed between the first connection portion P321 and the second connection portion P322. An orthographic projection of the first hollow portion QB1 on the substrate 10 may overlap with an orthographic projection of the fourth portion P4 on the substrate 10. The sum of the widths of the first connection portion P321 and the second connection portion P322 in the second direction Y may be the width of the fourth sub-portion P32 in the second direction Y.

In some embodiments, such as the embodiment shown in FIG. 9, along the first direction X, a length L1 of the first hollow portion QB1 is greater than or equal to the length L2 of the fourth portion P4. Such configuration can prevent the first connection portion P321 and the second connection portion P322 from being connected in the second direction Y, thereby reducing the area of the fourth sub-portion P32 to a greater extent.

In some embodiments, such as the embodiment shown in FIG. 8 and FIG. 9, the display panel 01 includes a first data signal line PAM_Data for transmitting a first data voltage to the pixel circuit 11. The first data signal line PAM_Data may be a first metal trace ZX1.

In some embodiments, such as the embodiment shown in FIG. 8 and FIG. 9, where the second node N2 is the position in the pixel circuit 11 at which a via hole connects to the light-emitting unit 12, a driving trace An is provided between the third electrode 23 (drain) of the second light-emitting control transistor T2 and the second node N2. The driving trace An may be integrally formed with the third electrode 23 of the second light-emitting control transistor T2. The driving trace An may also be the first metal trace ZX1.

In some embodiments of the present disclosure, the display panel 01 may include a plurality of first metal traces ZX1, and the third portion P3 of the first light-emitting control signal line EM1 may also include a plurality of fourth sub-portions P32. The fourth sub-portions P32 may adopt the same design or different designs.

In some embodiments, such as the embodiment shown in FIG. 8, both the first data signal line PAM_Data and the driving trace An are the first metal traces ZX1. In different fourth sub-portions P32, both the first connection portion P321 and the second connection portion P322 are structures connected in the second direction Y.

In some embodiments, such as the embodiment shown in FIG. 9, both the first data signal line PAM_Data and the driving trace An are the first metal traces ZX1. In different fourth sub-portions P32, both the first connection portion P321 and the second connection portion P322 are structures provided with a first hollow portion QB1 therebetween.

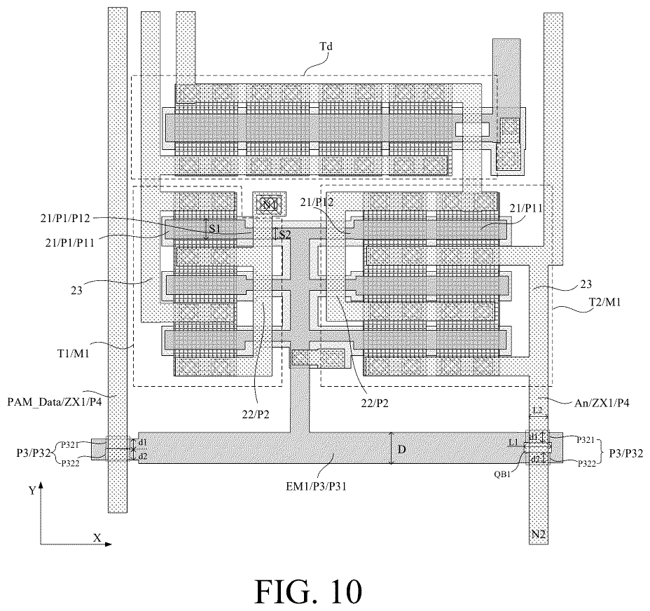

In some embodiments, such as the embodiment shown in FIG. 10, which is a partial schematic layout diagram of another pixel circuit according to an embodiment of the present disclosure, both the first data signal line PAM_Data and the driving trace An are the first metal traces ZX1. In a part of the fourth sub-portion P32, the first connection portion P321 is connected to the second connection portion P322 in the second direction Y. In the part of the fourth sub-portion P32, a first hollow portion QB1 is formed between the first connection portion P321 and the second connection portion P322.

For example, according to the embodiment shown in FIG. 10, in the fourth sub-portion P32 overlapping with the first data signal line PAM_Data, the first connection portion P321 and the second connection portion P322 are connected in the second direction Y. In the fourth sub-portion P32 overlapping with the driving trace An, a first hollow portion QB1 is formed between the first connection portion P321 and the second connection portion P322.

It should be noted that, when the third portion P3 includes the third sub-portion P31 and the fourth sub-portion P32 having different widths, in the above embodiments describing the width of the third portion P3, the width D of the third portion P3 in the second direction Y is the width D of the third sub-portion P31 in the second direction Y in some embodiments.

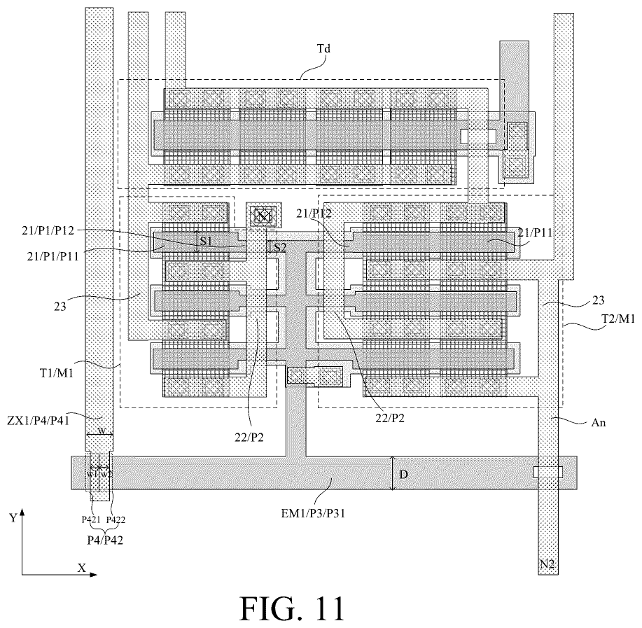

FIG. 11 is a partial schematic layout diagram of another pixel circuit according to an embodiment of the present disclosure.

In an embodiment of the present disclosure, as shown in FIG. 11, the first metal trace ZX1 includes a fourth portion P4 extending along the second direction Y, and the fourth portion P4 includes a fifth sub-portion P41 and a sixth sub-portion P42 connected to each other. An orthographic projection of the sixth sub-portion P42 on the substrate 10 overlaps with an orthographic projection of the third portion P3 on the substrate 10.

In some embodiments, the sixth sub-portion P42 includes a third connection portion P421 and a fourth connection portion P422 that are connected to the fifth sub-portion P41. The width of the third connection portion P421 in the first direction X is w1, and the width of the fourth connection portion P422 in the first direction X is w2. The sum of the width of the third connection portion P421 and the width of the fourth connection portion P422 in the first direction X may be a width of the sixth sub-portion P42 in the first direction X. A width of the fifth sub-portion P41 in the first direction X is W, and W>w1+w2. W may be a length L2 of the fourth portion P4 in the first direction X in the above embodiments.

In some embodiments, such as the embodiment shown in FIG. 11, the sixth sub-portion P42 is a continuous structure in the first direction X. The third connection portion P421 is connected to the fourth connection portion P422 in the first direction X, and the sixth sub-portion P42 is designed to be “necking” relative to the fifth sub-portion P41.

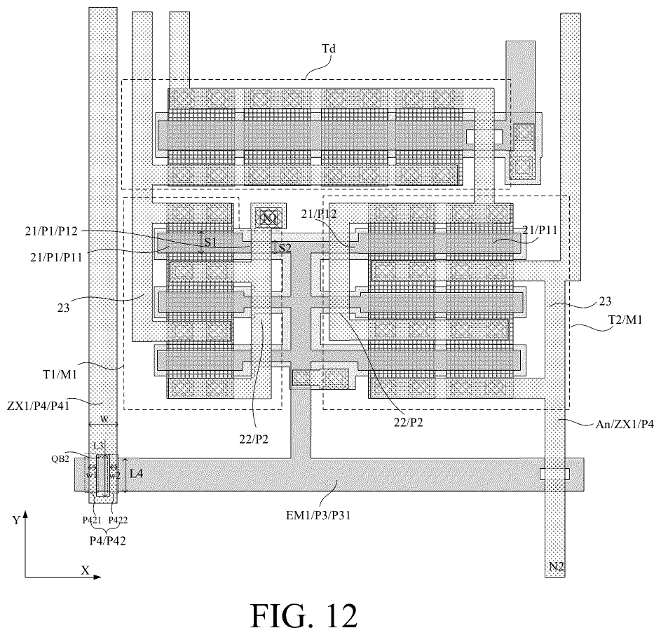

FIG. 12 is a partial schematic layout diagram of another pixel circuit according to an embodiment of the present disclosure. In some embodiments, the sixth sub-portion P42 is a discontinuous structure in the first direction X. The third connection portion P421 and the fourth connection portion P422 are arranged along the first direction X. A second hollow portion QB2 is formed between the third connection portion P421 and the fourth connection portion P422. An orthographic projection of the second hollow portion QB2 on the substrate 10 overlaps with an orthographic projection of the third portion P3 on the substrate 10.

In some embodiments, such as the embodiment shown in FIG. 12, in the second direction Y, the length of the second hollow portion QB2 is greater than the length of the third portion P3. In this way, the third connection portion P421 and the fourth connection portion P422 can be prevented from being connected in the first direction X, so as to facilitate reducing the area of the sixth sub-portion P42 to a greater extent. Herein, the length of the third portion P3 in the second direction Y may refer to the length of a part of the third portion P3 that overlaps with the sixth sub-portion P42.

In some embodiments of the present disclosure, the sixth sub-portion P42 is configured with a smaller width in the first direction X, reducing the overlapping area of the sixth sub-portion P42 and the third portion P3 in the direction perpendicular to the plane of the display panel 01. Furthermore, this configuration reduces the parasitic capacitance between the fourth portion P4 and the third portion P3 in the first light-emitting control signal line EM1, thereby further reducing the load on the first light-emitting control signal line EM1 and enhancing the response speed of the first transistor M1.

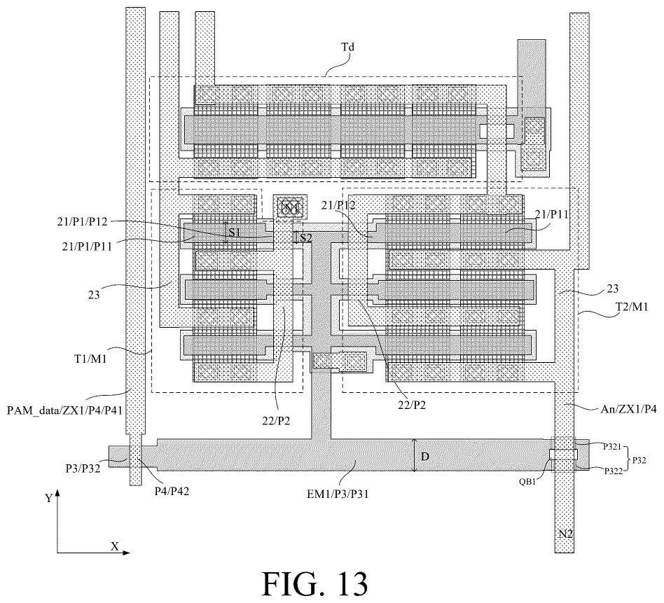

FIG. 13 is a partial schematic layout diagram of another pixel circuit according to an embodiment of the present disclosure. In some embodiments, in the direction perpendicular to the plane of the display panel 01, the fourth sub-portion P32 of the third portion P3 overlaps with the sixth sub-portion P42 of the fourth portion P4. In the overlapping regions of the fourth sub-portion P32 and the sixth sub-portion P42, the width of the fourth sub-portion P32 in the second direction Y may be reduced, and the width of the sixth sub-portion P42 in the first direction X may likewise be reduced, thereby further reducing the parasitic capacitance between the fourth sub-portion P32 and the sixth sub-portion P42.

Further, the width of only one of the fourth sub-portion P32 and the sixth sub-portion P42 that overlap with each other may be reduced, thereby achieving the purpose of reducing the parasitic capacitance between the two.

In some embodiments, such as the embodiment shown in FIG. 13, both the first data signal line PAM_Data and the driving trace An are the first metal trace ZX1. At the overlapping position of the first data signal line PAM_Data and the third portion P3 in the first light-emitting control signal line EM1, both the width of the fourth sub-portion P32 of the third portion P3 in the second direction Y and the width of the sixth sub-portion P42 of the first data signal line PAM_Data in the first direction X are reduced. At the overlapping position between the driving trace An and the third portion P3 of the first light-emitting control signal line EM1, only the width of the fourth sub-portion P32 of the third portion P3 in the second direction Y may be reduced. In this way, while reducing the load on the first light-emitting control signal line EM1, the driving trace An can be ensured to be relatively wide. A large light-emitting driving current flows through the driving trace An, which is beneficial to prevent the driving trace An from overheating.

Referring to the exemplary embodiments depicted in FIG. 8 through FIG. 13, both the first light-emitting control transistor T1 and the second light-emitting control transistor T2 may be the first transistor M1. In some embodiments, the first electrode 21 of the first light-emitting control transistor T1 is electrically connected to the first electrode 21 of the second light-emitting control transistor T2. That is, the gate of the first light-emitting control transistor T1 is electrically connected to the gate of the second light-emitting control transistor T2, and the first light-emitting control transistor T1 and the second light-emitting control transistor T2 may maintain the same switching state.

As can be understood from the foregoing analysis, a light-emitting driving current generated by the pixel circuit 11 may flow through the first light-emitting control transistor T1 and the second light-emitting control transistor T2. By configuring both the first light-emitting control transistor T1 and the second light-emitting control transistor T2 as the first transistor M1, the load of the driving signals required by the first light-emitting control transistor T1 and the second light-emitting control transistor T2 may be reduced, thereby improving the response speed of the first light-emitting control transistor T1 and the second light-emitting control transistor T2 and further enhancing the response speed of the light-emitting unit 12.

Further, the first electrode 21 of the first light-emitting control transistor T1 may be electrically connected to the first electrode 21 of the second light-emitting control transistor T2. As a result, both the first light-emitting control transistor T1 and the second light-emitting control transistor T2 may receive the same driving signal, thereby reducing the number of driving signal lines required for driving the first light-emitting control transistor T1 and the second light-emitting control transistor T2. This may further reduce the complexity of the layout of the pixel circuit 11 and simplify the design of the layout of the pixel circuit 11.

In some embodiments, such as the embodiments shown in FIG. 8 through FIG. 13, the first light-emitting control transistor T1 and the second light-emitting control transistor T2 are arranged along the first direction X, and the first electrode 21 of the first light-emitting control transistor T1 is electrically connected to the first light-emitting control signal line EN1. It should be understood that the first electrode 21 of the second light-emitting control transistor T2 may also be electrically connected to the first light-emitting control signal line EM1. The first light-emitting control signal line EM1 may be configured to transmit a driving signal to the first light-emitting control transistor T1 and the second light-emitting control transistor T2.

In some embodiments, the first light-emitting control signal line EM1 includes a third portion P3 extending along the first direction X, and the third portion P3 is located at a side of the first light-emitting control transistor T1 or the second light-emitting control transistor T2 away from the first driving transistor Td. That is, the third portion P3, the first light-emitting control transistor T1, and the first driving transistor Td may be sequentially arranged along the second direction Y, or the third portion P3, the second light-emitting control transistor T2, and the first driving transistor Td may be sequentially arranged along the second direction Y.

Because the first electrode 21 of the first light-emitting control transistor T1 and the first electrode 21 of the second light-emitting control transistor T2 may both include the first portion P1 extending along the first direction X, the first light-emitting control transistor T1 and the second light-emitting control transistor T2 may be arranged along the first direction X. Such an arrangement may be beneficial to aligning the first portion P1 of the first light-emitting control transistor T1 and the first portion P1 of the second light-emitting control transistor T2, so as to facilitate electrical connection between the first portion P1 of the first light-emitting control transistor T1 and the first portion P1 of the second light-emitting control transistor T2. It may further facilitate electrical connection between the first electrode 21 of the first light-emitting control transistor T1 and the first electrode 21 of the second light-emitting control transistor T2.

As can be understood from the foregoing analysis, the first driving transistor Td may be electrically connected to the first light-emitting control transistor T1 and the second light-emitting control transistor T2, and the third portion P3 may also be electrically connected to the first light-emitting control transistor T1 and the second light-emitting control transistor T2. The first driving transistor Td and the third portion P3 may be arranged on opposite sides of the first light-emitting control transistor T1 or on opposite sides of the second light-emitting control transistor T2, which may reduce mutual interference between the electrical connections of the first driving transistor Td and the third portion P3 with the first light-emitting control transistor T1 and the second light-emitting control transistor T2.

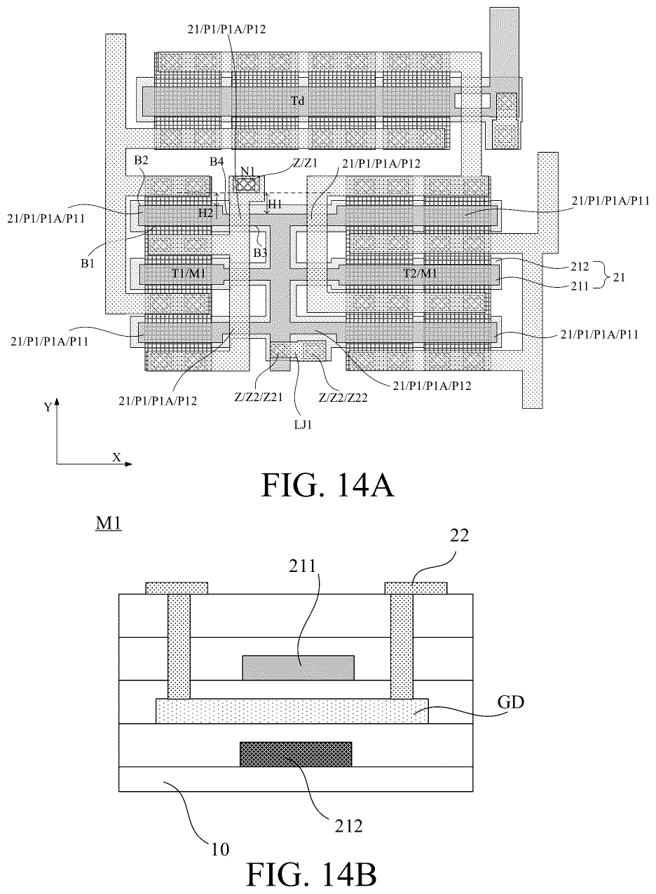

FIG. 14A is a partial schematic layout diagram of another pixel circuit according to an embodiment of the present disclosure. In some embodiments, the first electrode 21 of the first transistor M1 includes a plurality of first portions P1 arranged along the second direction Y. The first portions P1 includes an edge first portion PIA adjacent to the via hole Z. That is, the edge first portion PIA is located at a side of the first electrode 21 adjacent to the via hole Z.

In some embodiments, such as the embodiment shown in FIG. 14A, the via hole Z includes a via hole Z1 between the first node N1 and the first power line PAM_VDD (not shown in the drawing). The via hole Z1 may be located on a side of the first transistor M1 adjacent to the first driving transistor Td. Further, the via hole Z further may include a via hole Z2 located on a side of the first transistor M1 away from the first driving transistor Td. Additionally, the via hole Z2 may include via holes Z21 and Z22. The first portion P1 adjacent to the via hole Z1 is an edge first portion PIA, and the first portion P1 adjacent to the via hole Z2 may also be an edge first portion PIA.

FIG. 14B is a schematic cross-sectional view of the first transistor shown in FIG. 14A. In some embodiments, the first electrode 21 includes a first sub-electrode 211 and a second sub-electrode 212. The first sub-electrode 211 is located at a side of the channel GD away from the substrate 10, and the second sub-electrode 212 is located at a side of the channel GD adjacent to the substrate 10. The first sub-electrode 211 is electrically connected to the second sub-electrode 212. That is, the first transistor M1 may have a top-bottom double-gate structure, and a top gate and a bottom gate of the first transistor M1 receive the same signal. The via hole Z2 is a via hole for electrically connecting the first sub-electrode 211 and the second sub-electrode 212.

For the convenience of traces, as shown in FIG. 14A, the first sub-electrode 211 may be electrically connected to a connection line LJ1 through the via hole Z21, and the connection line LJ1 may be electrically connected to the second sub-electrode 212 through the via hole Z22, thereby achieving electrical connection between the first sub-electrode 211 and the second sub-electrode 212. The connection line LJ1 may be in the same layer as the second electrode 22 of the first transistor M1.

In some embodiments, in the edge first portion PIA, the first sub-portion P11 includes a first side edge B1 and a second side edge B2 that are opposite to each other along the second direction Y, and the second side edge B2 is located at a side of the first side edge B1 adjacent to the via hole Z. The second sub-portion P12 includes a third side edge B3 and a fourth side edge B4 that are opposite to each other along the second direction Y, and the fourth side edge B4 is located at a side of the third side edge B3 adjacent to the via hole Z. It should be noted that the via hole Z herein refers to a via hole adjacent to the edge first portion PIA.

In some embodiments, the second sub-portion P12 is a continuous structure in the second direction Y. That is, the second sub-portion P12 is designed to be “necking” relative to the first sub-portion P11. In the second direction Y, a distance H1 between the fourth side edge B4 and the via hole Z is greater than a distance H2 between the second side edge B2 and the via hole Z. That is, in the edge first portion PIA, the second sub-portion P12 is retracted toward the side away from the via hole Z relative to the first sub-portion P11. It can be understood that in the second direction Y, the first portions P1 may include two edge first portions PIA.

In some embodiments of the present disclosure, the second sub-portion P12 in the edge first portion PIA is retracted, so as to avoid the via hole Z located at the edge first portion PIA, which facilitates reducing mutual interference between the edge first portion PIA and the via hole Z.

In some embodiments, such as the embodiment shown in FIG. 14A, the first transistor M1 includes a first light-emitting control transistor T1 and a second light-emitting control transistor T2. The second sub-portion P12 in the edge first portion PIA is retracted, so as to avoid the via hole Z1 and the via hole Z2, thereby reducing overlapping between the second sub-portion P12 in the edge first portion PIA and interlayer materials at the via hole Z1 or the via hole Z2, which facilitates further reducing the load on the first portion P1 of the first transistor M1.

In some embodiments, such as the embodiment shown in FIG. 14A, in the same edge first portion PIA, the first side edge B1 of the first sub-portion P11 and the third side edge B3 of the second sub-portion P12 are located in the same plane. Based on such an arrangement, in the edge first portion PIA, the constant width of the second sub-portion P12 may be advantageous in that it may increase the retraction degree of the second sub-portion P12, so as to better avoid the via hole Z at the edge first portion PIA.

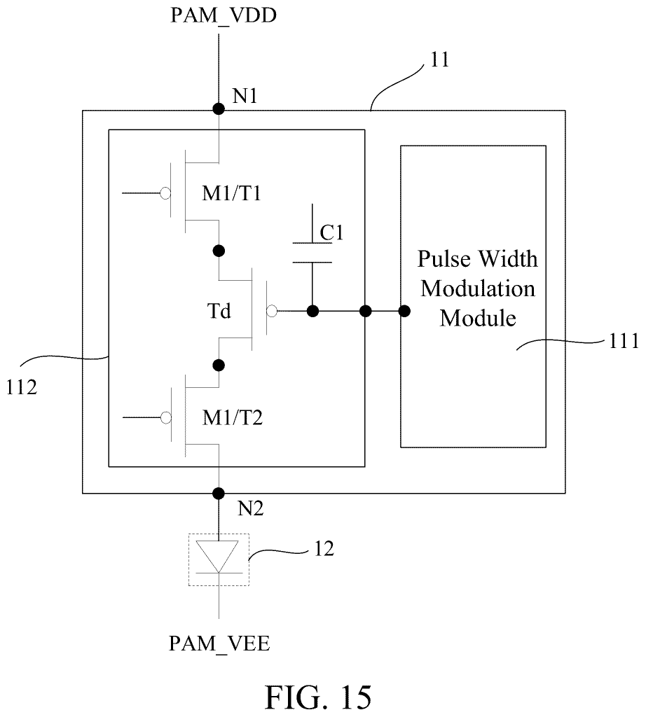

FIG. 15 is a schematic diagram of another pixel circuit according to an embodiment of the present disclosure.

In some embodiments, the pixel circuit 11 includes a pulse width modulation module 111 and an amplitude modulation module 112 that are electrically connected to each other, and the amplitude modulation module 112 includes a first transistor M1. That is, the first light-emitting control transistor T1, the first driving transistor Td, and the second light-emitting control transistor T2 in the foregoing embodiments may be located in the amplitude modulation module 112 of the pixel circuit 11. FIG. 15 only schematically shows that the first light-emitting control transistor T1 and the second light-emitting control transistor T2 are the first transistor M1.

In some embodiments, the amplitude modulation module 112 is configured to provide a light-emitting driving current to the light-emitting unit 12, and control a light-emitting efficiency of the light-emitting unit 12 by adjusting an amplitude of the light-emitting driving current. The light-emitting driving current may be a constant driving current, so as to drive the light-emitting unit 12 with a better light-emitting driving current, to ensure that the light-emitting unit 12 works in an optimal state, and to facilitate achieving higher light-emitting efficiency and better display effect.

In some embodiments, the pulse width modulation module 111 is configured to control the duration for which the amplitude modulation module 112 provides the light-emitting driving current to the light-emitting unit 12, thereby controlling the light-emitting duration of the light-emitting unit 12. It should be understood that the brightness of the light emitted by the light-emitting unit 12 can be controlled by controlling the light-emitting duration of the light-emitting unit 12 (that is, adjusting the light-emitting duty cycle of the light-emitting unit 12).

Because the amplitude modulation module 112 is configured to provide the light-emitting driving current to the light-emitting unit 12 in such embodiments, the speed at which the amplitude modulation module 112 generates the light-emitting driving current or cuts off the light-emitting driving current will affect the response speed of the light-emitting unit 12. In some embodiments of the present disclosure, the first transistor M1 is located in the amplitude modulation module 112, as can be understood from the foregoing analysis, which facilitates reducing the load of the driving signal of the transistor in the amplitude modulation module 112 and improving the response speed of the transistor in the amplitude modulation module 112, and further facilitates improving the response speed of the light-emitting unit 12.

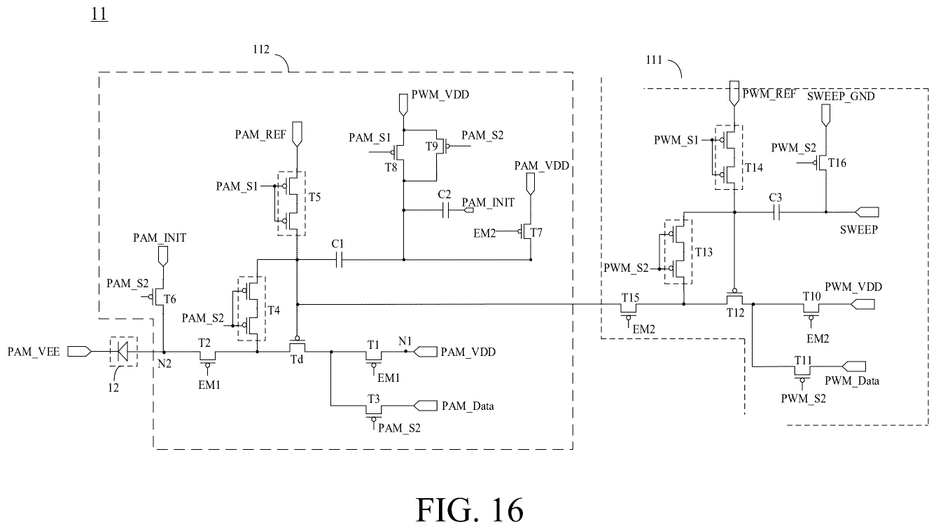

FIG. 16 is a schematic diagram of a pixel circuit according to an embodiment of the present disclosure. In some embodiments, the amplitude modulation module 112 includes a first light-emitting control transistor T1, a first driving transistor Td, a second light-emitting control transistor T2, an amplitude data writing transistor T3, an amplitude compensation transistor T4, an amplitude gate reset transistor T5, an amplitude reset transistor T6 and a first capacitor C1. The first light-emitting control transistor T1 has a source electrically connected to the first power line PAM_VDD, and a drain electrically connected to a source of the first driving transistor Td. The second light-emitting control transistor T2 has a source electrically connected to a drain of the first driving transistor Td, and a drain electrically connected to a first electrode of the light-emitting unit 12. The amplitude data writing transistor T3 has a source electrically connected to the first data signal line PAM_Data, and a drain electrically connected to the source of the first driving transistor Td. The amplitude compensation transistor T4 has a source electrically connected to the drain of the first driving transistor Td, and a drain electrically connected to a gate of the first driving transistor Td. The amplitude gate reset transistor T5 has a source electrically connected to the first reset signal line PAM_REF, and a drain electrically connected to the gate of the first driving transistor Td. The amplitude reset transistor T6 has a source electrically connected to the second reset signal line PAM_INIT, and a drain electrically connected to the first electrode of the light-emitting unit 12.

In some embodiments, the gate of the first light-emitting control transistor T1 and the gate of the second light-emitting control transistor T2 receive a first amplitude light-emitting control signal provided by the first light-emitting control signal line EM1. The gate of the amplitude gate reset transistor T5 may receive a first scanning signal provided by the first scanning signal line PAM_S1. The gates of the amplitude data writing transistor T3, the amplitude compensation transistor T4 and the amplitude reset transistor T6 may receive a second scanning signal provided by the second scanning signal line PAM_S2.

The pulse width modulation module 111 may include a third light-emitting control transistor T10, a pulse width data writing transistor T11, a second driving transistor T12, a pulse width compensation transistor T13, a pulse width gate reset transistor T14, a third light-emitting control transistor T15 and a third capacitor C3.

In some embodiments, the third light-emitting control transistor T10 has a source electrically connected to the third power line PWM_VDD, and a drain electrically connected to a source of the second driving transistor T12. The fourth light-emitting control transistor T15 has a source electrically connected to a drain of the second driving transistor T12, and a drain electrically connected to a gate of the first driving transistor Td in the amplitude modulation module 112. The pulse width data writing transistor T11 has a source electrically connected to the second data signal line PWM_Data, and a drain electrically connected to the source of the second driving transistor T12. The pulse width compensation transistor T13 has a source electrically connected to the drain of the second driving transistor T12, and a drain electrically connected to the gate of the second driving transistor T12. In some embodiments, the pulse width gate reset transistor T14 has a source electrically connected to the third reset signal line PWM_REF, and a drain electrically connected to the gate of the second driving transistor T12. One electrode plate of the third capacitor C3 may be electrically connected to the gate of the second driving transistor T12, and the other electrode plate of the third capacitor C3 is electrically connected to a swept-frequency signal line SWEEP.

A gate of the third light-emitting control transistor T10 and a gate of the fourth light-emitting control transistor T15 may receive a first pulse width light-emitting control signal provided by the second light-emitting control signal line EM2. A gate of the pulse width gate reset transistor T14 may receive a third scanning signal provided by the third scanning signal line PWM_S1. A gate of the pulse width data writing transistor T11 and a gate of the pulse width compensation transistor T13 may receive a fourth scanning signal provided by the fourth scanning signal line PWM_2.

In some embodiments, the pulse width modulation module 111 further includes a swept-frequency transistor T16, and the swept-frequency transistor T16 is connected in series between a swept-frequency constant voltage signal line SWEEP_GND and a third capacitor C3 (for example, an electrode plate of the third capacitor C3 connected to the swept-frequency signal line SWEEP). A gate of the swept-frequency transistor T16 may receive a fourth scanning signal provided by the fourth scanning signal line PWM_S2. Under the control of the fourth scanning signal, the swept-frequency transistor T16 may be turned on to transmit a swept-frequency constant voltage provided by the swept-frequency constant voltage signal line SWEEP_GND to the third capacitor C3. The swept-frequency constant voltage may be the same as a high level of the swept-frequency signal or the same as a low level of the swept-frequency signal. At this time, both the swept-frequency constant voltage signal line SWEEP_GND and the swept-frequency signal line SWEEP provide signals to one electrode plate of the third capacitor C3 (for example, the electrode plate of the third capacitor C3 connected to the swept-frequency signal line SWEEP), which can further ensure the stability of the potential of the electrode plate of the third capacitor C3 and thus reduce signal disturbances caused by surrounding signals.

Further, the amplitude modulation module 112 may further include a seventh transistor T7, and the seventh transistor T7 is connected in series between the first capacitor C1 and the first power line PAM_VDD. A gate of the seventh transistor T7 receives a first pulse width light-emitting control signal provided by the second light-emitting control signal line EM2. Under the control of the first pulse width light-emitting control signal, the seventh transistor T7 may be turned on to transmit the voltage provided by the first power line PAM_VDD to the first capacitor C1, so as to apply the voltage on the first power line PAM_VDD to the amplitude modulation module 112 in the light-emitting stage, thereby providing the driving current to the light-emitting unit 12.

In some embodiments, the amplitude modulation module 112 further includes an eighth transistor T8 and a ninth transistor T9. The eighth transistor T8 is connected in series between the third power line PWM_VDD and the first capacitor C1. A gate of the eighth transistor T8 may receive a first scanning signal provided by the first scanning signal line PAM_S1. Under the control of the first scanning signal, the eighth transistor T8 is turned on to transmit the voltage provided by the third power line PWM_VDD to the first capacitor C1. The ninth transistor T9 may also be connected in series between the third power line PWM_VDD and the first capacitor C1. A gate of the ninth transistor T9 may receive a second scanning signal provided by the second scanning signal line PAM_S2. Under the control of the second scanning signal, the ninth transistor T9 may be turned on to transmit the voltage provided by the third power line PWM_VDD to the first capacitor C1, so as to apply the voltage on the third power line PWM_VDD to the amplitude modulation module 112 when the amplitude modulation module 112 performs the reset phase and the data writing phase.

Further, the amplitude modulation module 112 may further include a second capacitor C2, and the second capacitor C2 is connected in series between the second reset signal line PAM_INIT and the first capacitor C1 and may be configured to stabilize a potential of the electrode plate of the first capacitor C1.

Regarding the pixel circuit 11, a reference voltage (such as a voltage on the third power line PWM_VDD) may be applied to the source of the second driving transistor T12 of the pulse width modulation module 111, and a varying potential is formed at the gate of the second driving transistor T12 through a data voltage on the second data signal line PWM_Data and a swept-frequency signal on the swept-frequency signal line SWEEP. When a voltage difference between the gate and the source of the second driving transistor T12 is greater than a threshold voltage of the second driving transistor T12, the second driving transistor T12 is in a cut-off state. At this time, the pulse width modulation module 111 does not provide a control signal to the amplitude modulation module 112, and the first driving transistor Td in the amplitude modulation module 112 provides a light-emitting driving current to the light-emitting unit 12 according to the voltage on the first data signal line PAM_Data.

As the voltage of the swept-frequency signal varies, the potential of the gate of the second driving transistor T12 may change synchronously until the voltage difference between the gate and the source of the second driving transistor T12 is less than or equal to the threshold voltage of the second driving transistor T12, at which point the second driving transistor T12 may be turned on. The second driving transistor T12 may transmit a voltage on the third power line PWM_VDD to the amplitude modulation module 112 as a cut-off voltage. As a result, the first driving transistor Td in the amplitude modulation module 112 may be cut off, thereby stopping providing the light-emitting driving current to the light-emitting unit 12. In this way, the pulse width modulation module 111 may effectively provide a PWM control signal to the amplitude modulation module 112. The duration of the light-emitting driving current output by the amplitude modulation module 112 may be controlled by adjusting the duty ratio of the PWM, thereby changing the effective light-emitting duration of the light-emitting unit 12 within one frame period and controlling the light-emitting brightness of the light-emitting unit 12.

It should be understood that the circuit structure of the pixel circuit 11 shown in FIG. 16 is merely a schematic diagram, and the pixel circuit structure provided by the present disclosure is not limited thereto, which is not specifically limited by the present disclosure.

In the pixel circuit 11, some transistors may adopt double-gate transistors. The double-gate transistor may include two transistors connected in series, and two gates of the double-gate transistor receive the same control signal.

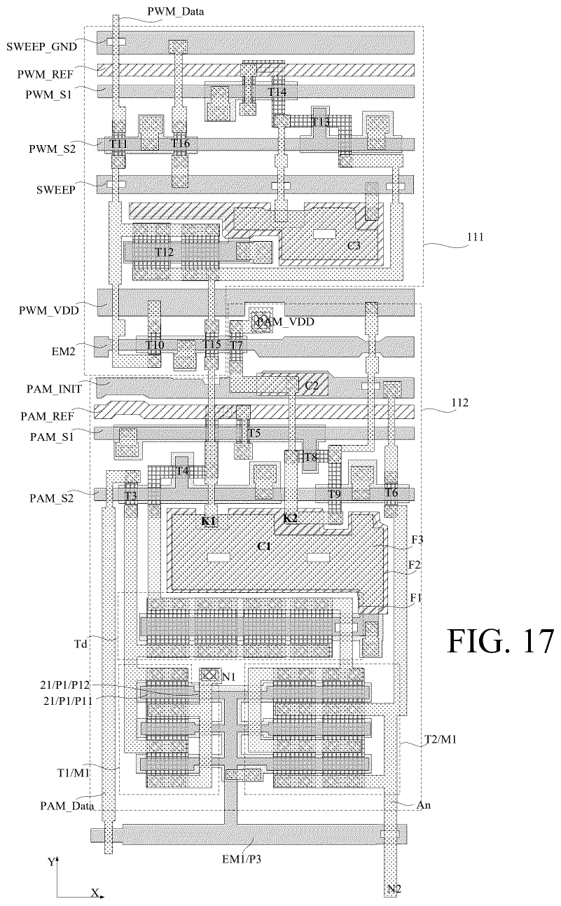

FIG. 17 is a schematic layout diagram of a pixel circuit according to an embodiment of the present disclosure. Referring to exemplary embodiments shown in FIG. 16 and FIG. 17, the amplitude modulation module 112 includes a first driving transistor Td and a first capacitor C1. The first capacitor C1 is located between the pulse width modulation module 111 and the first driving transistor Td. The pulse width modulation module 111 is electrically connected to the gate of the first driving transistor Td, and the pulse width modulation module 111 is electrically connected to the first capacitor C1. Further, the first capacitor C1 is also electrically connected to the gate of the first driving transistor Td.

In some embodiments, such as the embodiment shown in FIG. 16, the fourth light-emitting control transistor T15 in the pulse width modulation module 111 is electrically connected to the gate of the first driving transistor Td and one electrode plate of the first capacitor C1.

In some embodiments, such as the embodiment shown in FIG. 17, the pulse width modulation module 111, the first capacitor C1 and the first driving transistor Td are arranged along the second direction Y, which facilitates improving a space utilization rate of the pixel circuit 11 and prevents the pixel circuit 11 from occupying excessive space in the first direction X.

In some embodiments of the present disclosure, the first capacitor C1 is arranged between the pulse width modulation module 111 and the first driving transistor Td, which facilitates the electrical connection between the pulse width modulation module 111 and the first capacitor C1. The pulse width modulation module 111 may also be electrically connected to the gate of the first driving transistor Td through the electrode plate of the first capacitor C1.

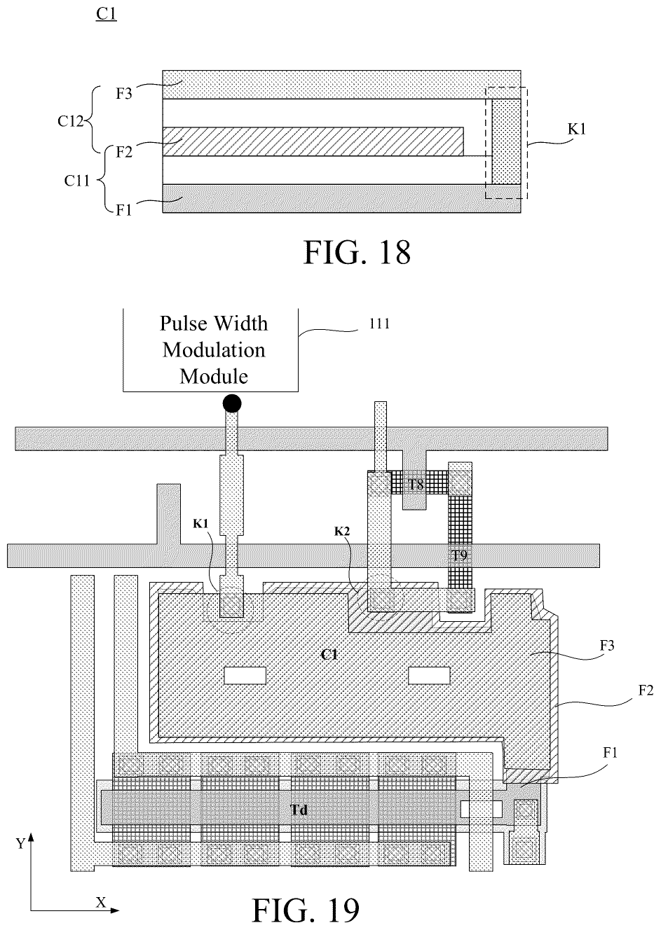

FIG. 18 is a schematic cross-sectional view of a first capacitor shown in FIG. 17. In an embodiment of the present disclosure, such as the embodiments shown in FIG. 17 and FIG. 18, the first capacitor C1 includes a first sub-capacitor C11 and a second sub-capacitor C12. The first sub-capacitor C11 includes a first electrode plate F1 and a second electrode plate F2, and the second sub-capacitor C12 includes a second electrode plate F2 and a third electrode plate F3. The first electrode plate F1 is connected to the third electrode plate F3 through a via hole K1. The second electrode plate F2 is located between the first electrode plate F1 and the third electrode plate F3.

In some embodiments, the first electrode plate F1 is in the same layer as the gate of the first transistor M1, and the third electrode plate F3 is in the same layer as the source or drain of the first transistor M1.

Based on such an arrangement, the first capacitor C1 may form a double-layer capacitor structure, which is beneficial to increasing the capacitance value of the first capacitor C1, thereby improving the voltage stabilization capability of the first capacitor C1.

FIG. 19 is an enlarged schematic diagram of a first capacitor according to an embodiment of the present disclosure. In some embodiments, such as the embodiments shown in FIG. 17 and FIG. 19, the first electrode plate F1 is electrically connected to the gate of the first driving transistor Td, and the pulse width modulation module 111 is electrically connected to the third electrode plate F3. Because the third electrode plate F3 is electrically connected to the first electrode plate F1, the pulse width modulation module 111 may be electrically connected to the gate of the first driving transistor Td through the third electrode plate F3 and the first electrode plate F1.

In some embodiments, the pulse width modulation module 111 is connected to the third electrode plate F3 at a via hole K1, and the via hole K1 is located on a side of the first capacitor C1 adjacent to the pulse width modulation module 111, so as to reduce the connection length between the pulse width modulation module 111 and the first capacitor C1.

The second electrode plate F2 may be externally connected to another device through a via hole K2, and the via hole K2 may be located on a side of the first capacitor C1 adjacent to the pulse width modulation module 111. For example, the second electrode plate F2 may be electrically connected to the seventh transistor T7 (not shown in FIG. 19), the eighth transistor T8 and the ninth transistor T9 through the via hole K2.

In some embodiments of the present disclosure, such as the embodiment shown in FIG. 17, the first light-emitting control transistor T1 and the second light-emitting control transistor T2 are arranged along the first direction X, and the pixel circuit 11 further includes a first capacitor C1 electrically connected to the gate of the first driving transistor Td.

In the second direction Y, the first driving transistor Td may be located between the first light-emitting control transistor T1 and/or the second light-emitting control transistor T2 and the first capacitor C1.

That is, the first capacitor C1 may be located at a side of the first driving transistor Td away from the first light-emitting control transistor T1 and/or the second light-emitting control transistor T2.

As can be understood from the foregoing analysis, the first light-emitting control transistor T1 and the second light-emitting control transistor T2 may both be electrically connected to the first driving transistor Td, and the first capacitor C1 may be electrically connected to both the first driving transistor Td and the pulse width modulation module 111. Therefore, the first capacitor C1 may be arranged at a side of the first driving transistor Td away from the first light-emitting control transistor T1 and/or the second light-emitting control transistor T2, so as to avoid the connection between the first capacitor C1 and the pulse width modulation module 111 and to block the connection between the first light-emitting control transistor T1 and/or the second light-emitting control transistor T2 and the first driving transistor Td. This may reduce the number of cross-lines in the pixel circuit 11 and reducing the complexity of the layout of the pixel circuit 11.

Further, based on such a configuration, the first light-emitting control transistor T1, the second light-emitting control transistor T2, and the first driving transistor Td may be arranged relatively compactly, which facilitates shortening the path of the light-emitting driving current flowing through the first light-emitting control transistor T1, the second light-emitting control transistor T2 and the first driving transistor Td, and reducing the loss of the light-emitting driving current.

Referring to the exemplary embodiments shown in FIG. 16 and FIG. 17, the first light-emitting control signal line EM1, the second light-emitting control signal line EM2, the first scanning line PAM_S1, the second scanning line PAM_S2, the third scanning line PWM_S1, the fourth scanning line PWM_S2, the second reset signal line PAM_INIT, the third power line PWM_VDD, the swept-frequency signal line SWEEP, and the swept-frequency constant voltage signal line SWEEP_GND are arranged in the same layer as the first electrode 21 of the first transistor M1, that is, may be made of the same process and the same material. In this way, the preparation process of the pixel circuit is simplified, and the preparation cost is reduced.

The second light-emitting control signal line EM2 may be located at a side of the third power line PWM_VDD adjacent to the amplitude modulation module 112. Such an arrangement may facilitate the connection between the second light-emitting control signal line EM2 and the seventh transistor T7 in the amplitude modulation module 112, thereby reducing the cross-lines.

In some embodiments, the first reset signal line PAM_REF and the third reset signal line PWM_REF are in the same layer, and are in the same layer as the second electrode plate F2 of the first capacitor C1, which is beneficial to further simplifying the preparation process of the pixel circuit 11.

In some embodiments, the first data signal line PAM_Data is in the same layer as the second data signal line PWM_Data, and are in the same layer as the second electrode 22 of the first transistor M1.

It should be noted that, in FIG. 17, structures having the same filling pattern are located in the same film layer.

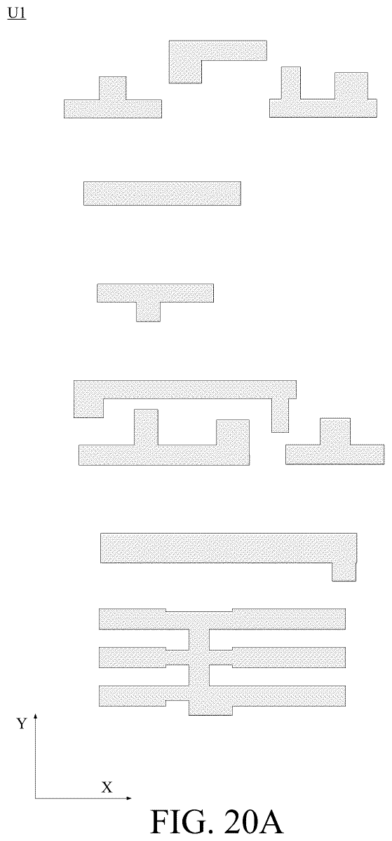

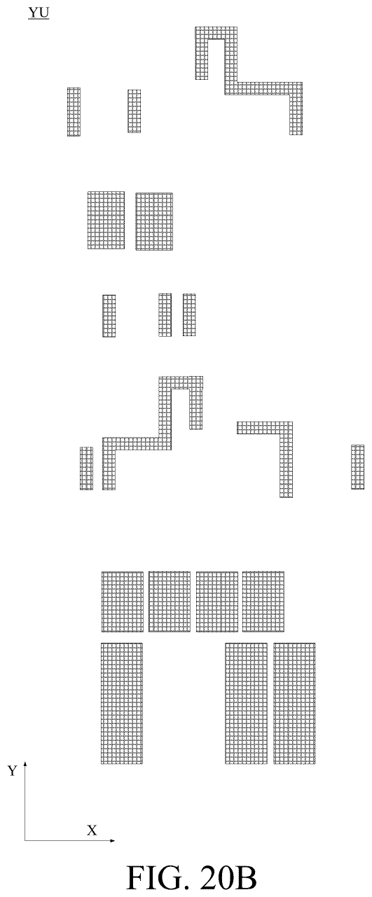

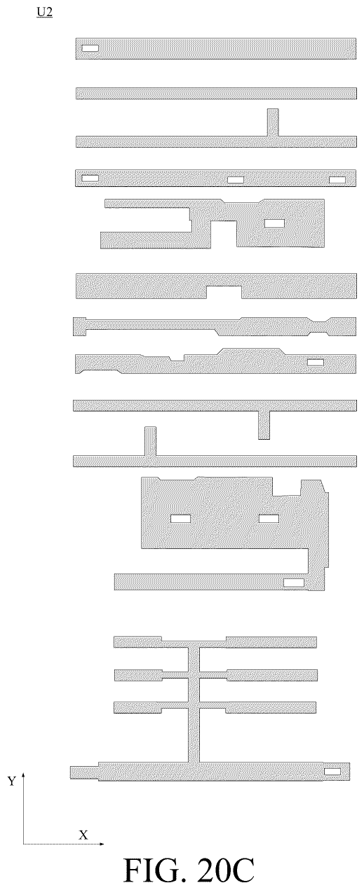

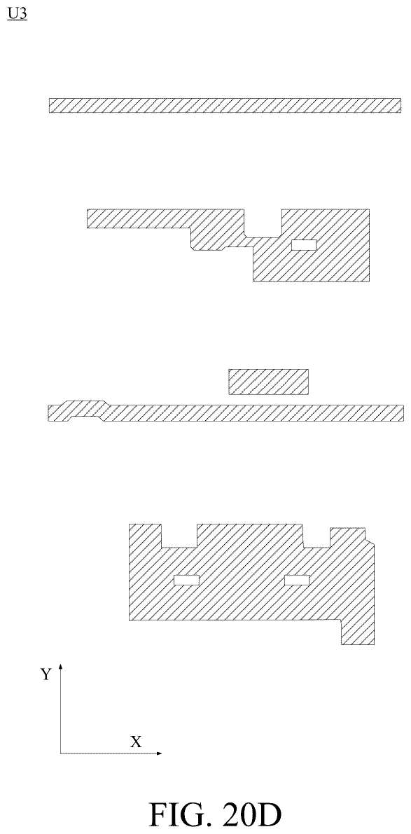

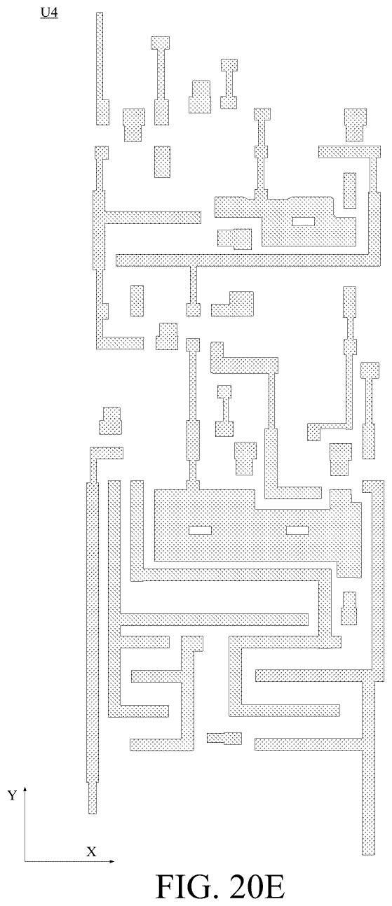

FIG. 20A is a schematic diagram of a film layer of a first metal layer in the pixel circuit shown in FIG. 17. FIG. 20B is a schematic diagram of a film layer of an active layer in the pixel circuit shown in FIG. 17. FIG. 20C is a schematic diagram of a film layer of a second metal layer in the pixel circuit shown in FIG. 17. FIG. 20D is a schematic diagram of a film layer of a third metal layer in the pixel circuit shown in FIG. 17. FIG. 20E is a schematic diagram of a film layer of a fourth metal layer in the pixel circuit shown in FIG. 17.

To facilitate understanding of the film layers of the pixel circuit shown in FIG. 17, the following briefly introduces the film layers of the pixel circuit 11 with reference to FIG. 17 and FIG. 20A through FIG. 20E. In some embodiments, in a thickness direction perpendicular to the plane of the display panel, the pixel circuit 11 includes a first metal layer U1, an active layer YU, a second metal layer U2, a third metal layer U3 and a fourth metal layer U4 that are sequentially arranged. The active layer YU includes a channel of the transistor as described above. The first metal layer U1 is located at a side of the active layer YU adjacent to the substrate. The first metal layer U1 may include the second sub-electrode 212 (a bottom gate of the transistor) as described above. The second metal layer U2 is located at a side of the active layer YU away from the substrate, and the second metal layer U2 may include the first sub-electrode 211 (a top gate of the transistor) and the first electrode plate F1 of the capacitor as described above. The third metal layer U3 is located at a side of the second metal layer U2 away from the substrate, and the third metal layer U3 may include the second electrode plate F2 of the capacitor as described above. The fourth metal layer U4 is located at a side of the third metal layer U3 away from the substrate, and the fourth metal layer U4 may include the second electrode 22 (a source or a drain) of the first transistor M1, the connection line LJ1, and the like as described above.

It should be noted that, in the display panel 01, the first power line PAN_VDD may be arranged at a side of the fourth metal layer U4 away from the substrate.

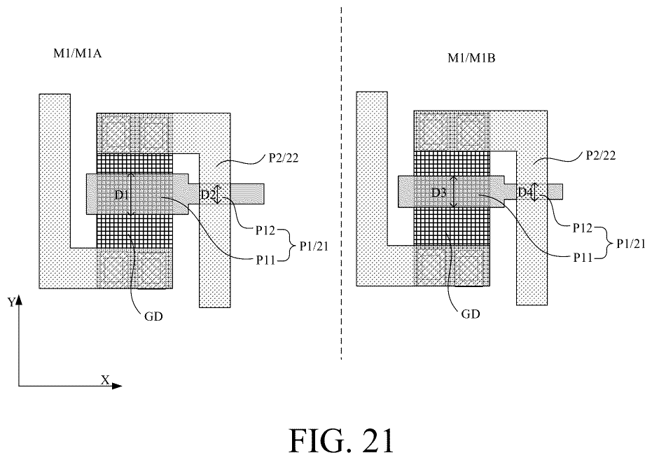

FIG. 21 is a schematic comparison diagram of a first transistor according to an embodiment of the present disclosure.

According to the embodiment shown in FIG. 21, the pixel circuit 11 includes a plurality of first transistors M1, and the first transistors M1 include a first-type transistor MIA and a second-type transistor M1B.

In the second direction Y, in the first-type transistor MIA, the width of the first sub-portion P11 is D1, and the width of the second sub-portion P12 is D2, D1>D2. In the second-type transistor M1B, the width of the first sub-portion P11 is D3, and the width of the second sub-portion P12 is D4, where D3>D4.

In some embodiments, D1>D3, and (D1−D2)>(D3−D4). That is, the first sub-portion P11 in the first-type transistor MIA is wider than the first sub-portion P11 in the second-type transistor MIB, and the degree of width reduction of the second sub-portion P12 in the first-type transistor MIA relative to the first sub-portion P11 is greater than the degree of width reduction of the second sub-portion P12 in the second-type transistor MIB relative to the first sub-portion P11.

Based on such an arrangement, increasing the diversity of the layout of the pixel circuit 11 is advantageous in that it facilitates reducing the width of the second sub-portion P12 in the first-type transistor MIA to a greater extent, which facilitates reducing the parasitic capacitance between the first electrode 21 and the second electrode 22 in the first-type transistor MIA to a greater extent. Furthermore, the parasitic capacitance between the first electrode 21 and the second electrode 22 is also kept relatively small in both the first-type transistor MIA and the second-type transistor M1B.

In some embodiments, the first driving transistor Td may be a first-type transistor MIA, and the first light-emitting control transistor T1 and/or the second light-emitting control transistor T2 may be a second-type transistor M1B.

Further, (D1−D2)/D1>(D3−D4)/D3 may also be configured to ensure that the parasitic capacitance between the first electrode and the second electrode remains relatively small in both the first-type transistor MIA and the second-type transistor M1B.

In some embodiments, such as the embodiment shown in FIG. 21, D2<D3, which facilitates ensuring that the width of the second sub-portion P12 in the first-type transistor MIA is relatively small, and further facilitates that the parasitic capacitance between the first electrode 21 and the second electrode 22 in the first-type transistor MIA is relatively small.

In some embodiments, such as the embodiment shown in FIG. 21, D2=D4, so that the second sub-portion P12 in the first-type transistor MIA and the second sub-portion P12 in the second-type transistor MIB may have the same width, which is beneficial to reducing the structural complexity of the first transistor M1, thereby reducing the design complexity of the layout of the pixel circuit 11.

In some embodiments, in the second direction Y, the width of the second sub-portion P12 in the first-type transistor MIA and the width of the second sub-portion P12 in the second-type transistor MIB are both the minimum values allowed by the preparation process.

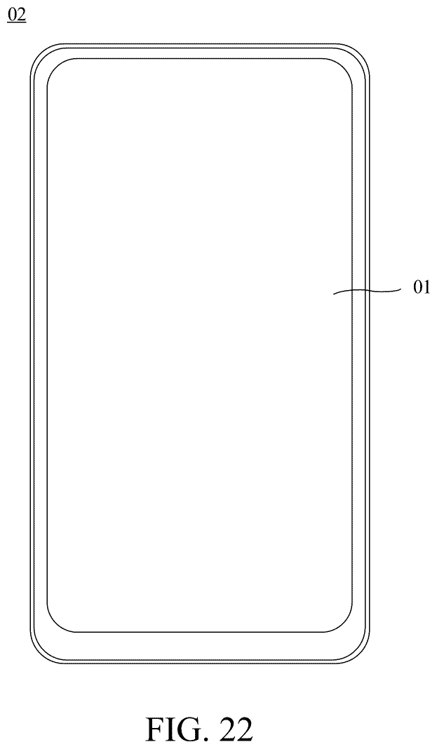

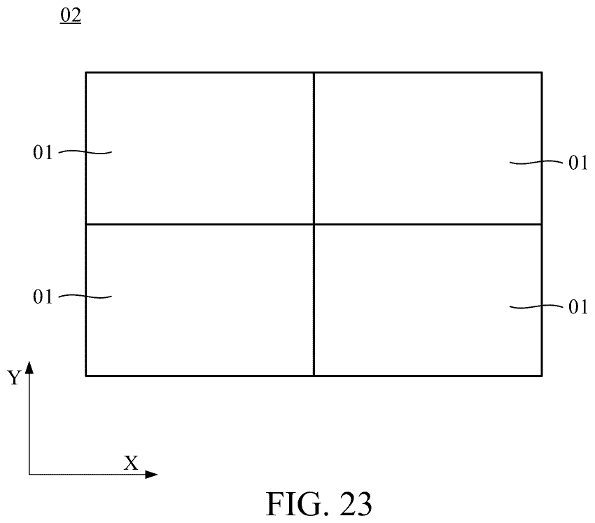

FIG. 22 is a schematic diagram of a display device according to an embodiment of the present disclosure. FIG. 23 is a schematic diagram of another display device according to an embodiment of the present disclosure.

In some embodiments, such as the embodiment shown in FIG. 22 and FIG. 23, a display device 02 includes the display panel 01 provided by the above embodiments. The display device may be a spliced display device, such as a frameless spliced display device. The spliced display device includes at least two display panels 01 described above, so as to be suitable for a large-screen display device having a display function.

At least two display panels 01 may be arranged along the first direction X, or at least two display panels 01 may be arranged along the second direction Y, which is not limited thereto and is not limited specifically in the present disclosure.

The display device 02 according to the embodiments of the present disclosure may be a mobile phone shown in FIG. 22, or may be a spliced display device shown in FIG. 23, or may be any electronic product having display function, including but not being limited to: a television, a laptop, and a desktop display, which is not specifically limited in the embodiments of the present disclosure.

In some embodiments of the display device 02, when the second sub-portion P12 is configured with a smaller width in the second direction Y, the area of the second sub-portion P12 is smaller, which facilitates decreasing an overlapping area between the second sub-portion P12 and the second portion P2 in the direction perpendicular to the plane of the display panel 01, and thus reducing the parasitic capacitance between the second sub-portion P12 and the second portion P2, thereby further reducing the parasitic capacitance between the first electrode 21 and the second electrode 22.

When driving the first transistor M1, the first electrode 21 or the second electrode 22 of the first transistor M1 may receive a driving signal. Because the parasitic capacitance between the first electrode 21 and the second electrode 22 is reduced, the load of the driving signal may be reduced, which facilitates improving the driving delay problem of the first transistor M1 and enhancing the display effect of the display panel 01.

The above descriptions are merely preferred embodiments of the present disclosure and are not intended to limit the present disclosure. It should be noted that any modifications, equivalent substitutions, improvements, and the like made within the spirit and principle of the present disclosure shall fall within the scope of the present disclosure.

What is claimed is:

1. A display panel, comprising:
a substrate; and
a pixel circuit and a light-emitting unit that are located on one side of the substrate, wherein the pixel circuit comprises a first node electrically connected to a first power line and a second node electrically connected to the light-emitting unit,
wherein the pixel circuit comprises a first transistor coupled between the first node and the second node,
wherein the first transistor comprises a first electrode and a second electrode;
wherein the first electrode comprises a first portion extending in a first direction, the second electrode comprises a second portion extending in a second direction, and the first direction intersects with the second direction;
wherein the first portion comprises a first sub-portion and a second sub-portion connected to each other, and an orthographic projection of the second sub-portion on the substrate overlaps with an orthographic projection of the second portion on the substrate, and
wherein, in the second direction, a width of the first sub-portion is greater than a width of the second sub-portion.

2. The display panel according to claim 1, wherein the first electrode is a gate, and the second electrode is a source or a drain.

3. The display panel according to claim 1,
wherein the pixel circuit comprises a first light-emitting control transistor, a first driving transistor, and a second light-emitting control transistor;
wherein the first light-emitting control transistor is coupled between the first node and the first driving transistor, and the second light-emitting control transistor is coupled between the second node and the first driving transistor; and
wherein at least one of the first light-emitting control transistor, the first driving transistor, or the second light-emitting control transistor is the first transistor.

4. The display panel according to claim 1,
wherein the first transistor comprises X sub-transistors, first electrodes of the X sub-transistors are connected to each other, second electrodes of the X sub-transistors are connected to each other, and third electrodes of the X sub-transistors are connected to each other; and
wherein X≥2 and X is an integer.

5. The display panel according to claim 1,
wherein a first electrode of the first transistor is electrically connected to a first light-emitting control signal line, and the first light-emitting control signal line comprises a third portion extending along the first direction; and
wherein, in the second direction, a width of the third portion is greater than a width of the first portion.

6. The display panel according to claim 5, wherein, in the second direction, the width of the third portion is D, and 5.6 μm<D≤15 μm.

7. The display panel according to claim 5, further comprising:
a first metal trace comprising a fourth portion extending along the second direction;
wherein the third portion comprises a third sub-portion and a fourth sub-portion connected to each other, and an orthographic projection of the fourth sub-portion on the substrate overlaps with an orthographic projection of the fourth portion on the substrate;
wherein the fourth sub-portion comprises a first connection portion connected to the third sub-portion, and a width of the first connection portion in the second direction is d1;
wherein the fourth sub-portion further comprises a second connection portion connected to the third sub-portion, and a width of the second connection portion in the second direction is d2; and
wherein a width of the third sub-portion in the second direction is D, and d1+d2<D.

8. The display panel according to claim 7,
Wherein the first connection portion and the second connection portion are arranged along the second direction, and a first hollow portion is formed between the first connection portion and the second connection portion; and
wherein an orthographic projection of the first hollow portion on the substrate overlaps with the orthographic projection of the fourth portion on the substrate.

9. The display panel according to claim 8, wherein in the first direction, a length of the first hollow portion is greater than or equal to a length of the fourth portion.

10. The display panel according to claim 1, wherein the pixel circuit comprises a pulse width modulation module and an amplitude modulation module that are electrically connected to each other, and the amplitude modulation module comprises the first transistor.

11. The display panel according to claim 10, wherein the amplitude modulation module comprises a first driving transistor and a first capacitor, the first capacitor is located between the pulse width modulation module and the first driving transistor, the pulse width modulation module is electrically connected to a gate of the first driving transistor, and the pulse width modulation module is connected to the first capacitor.

12. The display panel according to claim 11,
wherein the first capacitor comprises a first sub-capacitor and a second sub-capacitor;
wherein the first sub-capacitor comprises a first electrode plate and a second electrode plate, and the second sub-capacitor comprises a second electrode plate and a third electrode plate; and
wherein the first electrode plate and the third electrode plate are connected through a via hole.

13. The display panel according to claim 12, wherein the first electrode plate is connected to the gate of the first driving transistor, and the pulse width modulation module is connected to the third electrode plate.

14. The display panel according to claim 3,
wherein the first light-emitting control transistor and the second light-emitting control transistor are arranged along the first direction; and
wherein the pixel circuit further comprises a first capacitor, and, in the second direction, the first driving transistor is located between the first light-emitting control transistor and/or the second light-emitting control transistor and the first capacitor.

15. The display panel according to claim 3,
wherein the first light-emitting control transistor comprises X1 first sub-transistors connected in parallel, and the second light-emitting control transistor comprises X2 second sub-transistors connected in parallel;
wherein X1≥2, X2≥2, X1 and X2 are integers, and X1<X2.

16. The display panel according to claim 15, wherein a channel width-to-length ratio of the first sub-transistor is equal to a channel width-to-length ratio of the second sub-transistor.

17. The display panel according to claim 15,
wherein the first driving transistor comprises X3 third sub-transistors connected in parallel, wherein X3≥2 and X3 is an integer; and
wherein the X1 first sub-transistors are arranged in the second direction, the X2 second sub-transistors are arranged in an array in the first direction and the second direction, and the X3 third sub-transistors are arranged in the first direction.

18. The display panel according to claim 1,
wherein the first electrode of the first transistor comprises a plurality of first portions arranged along the second direction;
wherein the plurality of first portions comprise an edge first portion adjacent to a via hole;
wherein, in the edge first portion, the first sub-portion comprises a first side edge and a second side edge opposite to each other along the second direction, and the second side edge is located at a side of the first side edge adjacent to the via hole; and the second sub-portion comprises a third side edge and a fourth side edge opposite to each other along the second direction, and the fourth side edge is located at a side of the third side edge adjacent to the via hole; and
wherein, in the second direction, a distance from the fourth side edge to the via hole is greater than a distance from the second side edge to the via hole.

19. The display panel according to claim 3, wherein the first light-emitting control transistor and the second light-emitting control transistor each are the first transistor, and a first electrode of the first light-emitting control transistor is electrically connected to a first electrode of the second light-emitting control transistor.

20. A display device, comprising a display panel comprising:
a substrate; and
a pixel circuit and a light-emitting unit that are located on one side of the substrate, wherein the pixel circuit comprises a first node electrically connected to a first power line and a second node electrically connected to the light-emitting unit;
wherein the pixel circuit comprises a first transistor coupled between the first node and the second node;
wherein the first transistor comprises a first electrode and a second electrode; the first electrode comprises a first portion extending in a first direction, and the second electrode comprises a second portion extending in a second direction; and the first direction intersects with the second direction,
wherein the first portion comprises a first sub-portion and a second sub-portion connected to each other, and an orthographic projection of the second sub-portion on the substrate overlaps with an orthographic projection of the second portion on the substrate, and
wherein in the second direction, a width of the first sub-portion is greater than a width of the second sub-portion.
